(19) United States
(12) Patent Application Publication
(10) Pub. No.: US 2015/0243163 A1
(43) Pub. Date: Aug. 27, 2015

(54) Audio Based Remote Control Functionality

(71) Applicant: Biscotti Inc., Plano, TX (US)

(72) Inventor: Matthew B. Shoemake, Allen, TX (US)

(21) Appl. No.: 14/702,439

(22) Filed: May 1, 2015

Related U.S. Application Data
(63) Continuation-in-part of application No. 14/539,106, filed on Nov. 12, 2014.
Application No. 14/539,106 is a continuation-in-part of application No. 14/106,263, filed on Dec. 13, 2013.
Application No. 14/539,106 is a continuation-in-part of application No. 14/170,499, filed on Jan. 31, 2014.
Application No. 14/539,106 is a continuation-in-part of application No. 14/341,009, filed on Jul. 25, 2014.
Application No. 14/539,106 is a continuation-in-part of application No. 14/472,133, filed on Aug. 28, 2014.
Application No. 14/539,106 is a continuation-in-part of application No. 14/479,169, filed on Sep. 5, 2014.
Application No. 14/539,106 is a continuation-in-part of application No. 14/106,279, filed on Dec. 13, 2013.
Application No. 14/539,106 is a continuation-in-part of application No. 14/106,360, filed on Dec. 13, 2013, now Pat. No. 8,914,837.
Application No. 14/106,360 is a continuation-in-part of application No. 14/464,435, filed on Aug. 20, 2014.
(60) Provisional application No. 61/987,304, filed on May 1, 2014.
(60) Provisional application No. 61/737,506, filed on Dec. 14, 2012.
(60) Provisional application No. 61/759,621, filed on Feb. 1, 2013.
(60) Provisional application No. 61/858,518, filed on Jul. 25, 2013.
(60) Provisional application No. 61/872,603, filed on Aug. 30, 2013.
(60) Provisional application No. 61/874,903, filed on Sep. 6, 2013.
(60) Provisional application No. 61/877,928, filed on Sep. 13, 2013.

(51) Int. Cl. G08C 23/02; H03M 13/09; H04L 1/16; H04J 1/00

(52) U.S. Cl. CPC G08C 23/02; H04J 1/00; H03M 13/09; H04L 1/16

(57) ABSTRACT

Novel tools and techniques are described for providing remote control of consumer electronics devices, and, more particularly, for providing audio-based remote control of consumer electronics devices (which, in some cases, may not have dedicated remote controllers).

### CROSS-REFERENCES TO RELATED APPLICATIONS

This application claims the benefit, under 35 U.S.C. §119, of provisional U.S. Patent Application No. 61/987,304, filed May 1, 2014 by Shoemake et al. and titled “Virtual Remote Functionality” (attorney docket no. 0414.15-PR, referred to herein as the “'304 application”). This application is also a continuation-in-part of U.S. patent application Ser. No. 14/539,106, filed on Nov. 12, 2014 by Shoemake et al. and titled, “Automatic Content Filtering (attorney docket no. 0414.14, referred to herein as the” '106 application). The '106 application is a continuation-in-part of U.S. patent application Ser. No. 14/106,263, filed on Dec. 13, 2013 by Shoemake et al. and titled “Video Capture, Processing and Distribution System” (attorney docket no. 0414.06, referred to herein as the “'263 application”), which claims the benefit of provisional U.S. Patent Application No. 61/737,506, filed Dec. 14, 2012 by Shoemake et al. and titled “Video Capture, Processing and Distribution System” (attorney docket no. 0414.06-PR, referred to herein as the “'506 application”). The '106 application is also a continuation in part of U.S. patent application Ser. No. 14/170,499, filed on Jan. 31, 2014 by Shoemake et al. and titled “Video Mail Capture, Processing and Distribution” (attorney docket no. 0414.07, referred to herein as the “'499 application”), which claims the benefit of provisional U.S. Patent Application No. 61/759,621, filed Feb. 1, 2013 by Shoemake et al. and titled “Video Mail Capture, Processing and Distribution” (attorney docket no. 0414.07-PR, referred to herein as the “'621 application”). The '106 application is also a continuation-in part of U.S. patent application Ser. No. 14/341,009, filed on Jul. 25, 2014 by Shoemake et al. and titled “Video Calling and Conferencing Addressing” (attorney docket no. 0414.08, referred to herein as the “'009 application”), which claims the benefit of provisional U.S. Patent Application No. 61/858,518, filed Jul. 25, 2013 by Shoemake et al. and titled “Video Calling and Conferencing Addressing” (attorney docket no. 0414.08-PR, referred to herein as the “'518 application”). The '106 application is also a continuation in part of U.S. patent application Ser. No. 14/472,133, filed on Aug. 28, 2014 by Ahmed et al. and titled “Physical Presence and Advertising” (attorney docket no. 0414.10, referred to herein as the “'133 application”), which claims the benefit of provisional U.S. Patent Application No. 61/872,603, filed Aug. 30, 2013 by Ahmed et al. and titled “Physical Presence and Advertising” (attorney docket no. 0414.10-PR, referred to herein as the “'603 application”). The '106 application is also a continuation in part of U.S. patent application Ser. No. 14/479,169, filed on Sep. 5, 2014 by Shoemake et al. and titled “Virtual Window” (attorney docket no. 0414.11, referred to herein as the “'169 application”), which claims the benefit of provisional U.S. Patent Application No. 61/874,903, filed Sep. 6, 2013 by Shoemake et al. and titled “Virtual Window” (attorney docket no. 0414.11-PR, referred to herein as the “'903 application”). The '106 application is also a continuation in part of U.S. patent application Ser. No. 14/106,279, filed on Dec. 13, 2013 by Ahmed et al. and titled “Mobile Presence Detection” (attorney docket no. 0414.12, referred to herein as the “'279 application”), which claims the benefit of provisional U.S. Patent Application No. 61/877,928, filed Sep. 13, 2013 by Ahmed et al. and titled “Mobile Presence Detection” (attorney docket no. 0414.12-PR, referred to herein as the “'928 application”). The '106 application is also a continuation-in-part of U.S. patent application Ser. No. 14/106,360, (now U.S. Pat. No. 8,914,837) filed on Dec. 13, 2013 by Ahmed et al. and titled “Distributed Infrastructure” (attorney docket no. 0414.13, referred to herein as the “'360 application”). The '106 application is also a continuation-in-part of U.S. patent application Ser. No. 14/464,435, filed Aug. 20, 2014 by Shoemake et al. and titled “Monitoring, Trend Estimation, and User Recommendations” (attorney docket no. 0414.09, referred to herein as the “'435 application”).

This application may also be related to U.S. patent application Ser. No. 14/702,390 filed on May 1, 2015 by Shoemake et al. and titled “Virtual Remote Functionality” (attorney docket no. 0414.15, referred to herein as the “'390 application”), which claims the benefit of the '304 application.

The respective disclosures of these applications/patents (which this document refers to collectively as the “Related Applications”) are incorporated herein by reference in their entirety for all purposes.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to tools and techniques for providing remote control of consumer electronics devices, and, more particularly, to tools and techniques for providing audio-based remote control of consumer electronics devices.

### BACKGROUND

Consumer electronics products such as televisions, digital media players (including, without limitation Roku®, Apple TV®, and/or the like), Blu-ray players, and media recording and/or playback devices (including, but not limited to video cassette recorders, digital video recorders, stereo systems, and/or the like) come packaged with dedicated remote control devices when sold. These remote control devices may use infrared (non-visible) light or may use electromagnetic waves covering other ranges of the electromagnetic spectrum. These devices are human interface devices that allow a user to control the consumer electronics products. This communication may allow the user to perform functions such as navigating menu systems, entering text, controlling functionality of the consumer electronics products, and/or the like.

Several disadvantages regarding having a dedicated remote control device to control a consumer electronic device include, but are not necessarily limited to, the dedicated remote control device adding to the cost of the product, consumers accumulating large numbers of dedicated remote controls, the remote control device becoming lost due to potential infrequent use, and/or the like.

But, if a dedicated remote control device is not included with a consumer electronics product, some fundamental problems may arise. Consider an Apple TV, for example. It may be connected to the Internet using Wi-Fi. It comes with a remote control device. The remote control device is used to setup the digital media player. If the digital media player were connected to the Internet, a cell phone app could be used to communicate with the Apple TV and control it. But, the Apple TV cannot connect to the Internet without user input. In computer science terminology, this is referred to as a “deadlock situation.” There is no way to progress without the remote control device.

Latency minimization is also a concern with remote control devices. The user prefers a very quick response time from the consumer electronics product. The time for communication of a command from the remote control device (whether IR remote control or App) necessarily adds to the latency that the user experiences.

Further, consumer electronics devices, such as mentioned above, typically use either infrared based remote control functionality or other light-based remote control functionality, or a wired remote control functionality, but do not utilize audio-based (i.e., tone-based or audio-signal-based) remote control functionality

Hence, there is a need for more robust and scalable solutions for providing audio-based remote control of consumer electronics devices (some of which do not have or do not require dedicated remote controllers).

### BRIEF SUMMARY

A set of embodiments provides tools and techniques for providing audio-based remote control of consumer electronics devices (some of which do not have or do not require dedicated remote controllers).

Merely by way of example, some embodiments allow audio-based remote control of a consumer electronics device. Some embodiments allow for the consumer electronics device to be used by a user(s) without a dedicated remote control device at all.

The tools provided by various embodiments include, without limitation, methods, systems, and/or software products. Merely by way of example, a method might comprise one or more procedures, any or all of which are executed by a PDD and/or a computer system. Correspondingly, an embodiment might provide a PDD and/or a computer system configured with instructions to perform one or more procedures in accordance with methods provided by various other embodiments. Similarly, a computer program might comprise a set of instructions that are executable by a PDD and/or a computer system (and/or a processor therein) to perform such operations. In many cases, such software programs are encoded on physical, tangible, and/or non-transitory computer readable media (such as, to name but a few examples, optical media, magnetic media, and/or the like).

In an aspect, a method might comprise receiving, with a first user device, user input indicating user selection of one or more functions to be performed by a second user device, and generating, with the first user device, a first set of commands, based at least in part on the received user input. The method might further comprise generating, with the first user device, an audio-based set of commands, based at least in part on the first set of commands, and emitting, with one or more speakers of the first user device, the generated audio-based set of commands for instructing the second user device to perform the one or more functions.

In some embodiments, the first user device might comprise one of a dedicated remote control device associated with the second user device, a universal remote control device, or a mobile user device. The mobile user device might comprise one of a smart phone, a mobile phone, a tablet computer, a gaming console, a portable gaming device, a laptop computer, or a desktop computer. The second user device, in some cases, might comprise one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, or a consumer electronic device sold without a dedicated remote controller. In some instances, the second user device might comprise one of a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

Merely by way of example, in some embodiments, the audio-based set of commands might comprise a plurality of unique tones that are each mapped to a corresponding one of the one or more functions. The plurality of unique tones, in some instances, might comprise a plurality of audible tones. In some cases, emitting the generated audio-based set of commands might comprise emitting, with the one or more speakers of the first user device, the plurality of audible tones at a sound pressure level below auditory threshold (i.e., below 0 dB at 1 kHz). According to some embodiments, the plurality of unique tones might comprise at least one of a plurality of infra-sonic tones or a plurality of ultra-sonic tones. In some cases, the audio-based set of commands might comprise one or more masking audible tones overlaid on each of the at least one of the plurality of infra-sonic tones or the plurality of ultra-sonic tones. The one or more masking audible tones might be unrelated or unassociated with any functions of the second user device.

According to some embodiments, the plurality of unique tones might comprise a plurality of audible tones that are harmonics of each other. In some cases, the plurality of unique tones might comprise one or more musical cords. In some instances, the plurality of unique tones might comprise two or more unique tones that are classified into audibly distinguishable groups, each group being associated with a user device separate from other user devices associated with other groups. In some embodiments, the plurality of unique tones might comprise one or more tones that are correlated with at least one of phonetic sound of a command, meaning of a command, and/or evoked sense of a command, or the like. In some cases, the plurality of unique tones might comprise one or more tones each having at least one pattern embedded therein, wherein each tone, although audibly indistinguishable to a human, is distinguishable by a receiver from a combination of pattern and tone.

Merely by way of example, in some instances, generating the audio-based set of commands, based at least in part on the first set of commands, might comprise generating, with the first user device, an audio-based set of commands, based at least in part on the first set of commands, using forward error control (“FEC”) code. In some cases, the FEC code might comprise one of repetition code, binary convolutional code, block code, low density parity check code, and/or a combination of these codes, or the like.

In some embodiments, the method might further comprise modulating, with the first user device, the audio-based set of commands using orthogonal frequency-division multiplexing (“OFDM”), prior to emitting the generated audio-based set of commands. Alternatively or additionally, the method might comprise modulating, with the first user device, the audio-based set of commands using spreading sequence modulation, prior to emitting the generated audio-based set of commands. In some cases, the method might further comprise modifying, with the first user device, frequency range of sound of the generated audio-based set of commands based on at least one of frequency range of the one or more speakers or sampling rate used with the one or more speakers.

According to some embodiments, the audio-based set of commands might comprise a packet field, a packet header field, and a message field, and the method might further comprise performing, with the first user device and prior to emitting the generated audio-based set of commands, a cyclic redundancy check (“CRC”) on the audio-based set of commands, by appending a CRC check value for protecting at least one of the packet field, the packet header field, or the message field. In some cases, the audio-based set of commands might comprise at least one of a source address, a destination address, a target device type, or a target device model number. In some instances, the method might further comprise encrypting, with the first user device, the audio-based set of commands, prior to emitting the generated audio-based set of commands.

The method, in some embodiments, might further comprise measuring, with a microphone of the first user device, background noise level prior to emitting the generated audio-based set of commands. In such embodiments, emitting the generated audio-based set of commands might be performed based at least in part on a determination that the measured background noise level does not conflict with the generated audio-based set of commands when emitted. In some cases, the method might further comprise adjusting, with the first user device, volume of the one or more speakers based at least in part on the measured background noise level.

In some instances, the second user device might respond to the emitted generated audio-based set of commands with one of an audible acknowledgement (“ACK”) or an audible negative ACK (“NACK”). In some cases, the method might further comprise adjusting, with the first user device, volume of the one or more speakers in response to one of receiving NACK, not receiving ACK, volume level of ACK, and/or volume level of NACK from the second user device, or the like.

According to some embodiments, the user input might comprise one of a typed user input or a voice user input that does not match any of a preselected group of commands, and generating at least one of the first set of commands or the audio-based set of commands might comprise embedding the one of typed user input or voice user input as message data in the at least one of the first set of commands or the audio-based set of commands.

In another aspect, a method might comprise receiving, with a first user device, an audio-based set of commands emitted from one or more speakers of a second user device. The method might further comprise converting, with the first user device, the received audio-based set of commands into a first set of commands, wherein the first set of commands causes one of the first user device or a third user device to perform one or more functions.

According to some embodiments, the first user device might comprise one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

In alternative embodiments, the first user device might comprise an audio receiver (or intermediate device) that communicatively couples to the third user device. The third user device might comprise one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

The second user device might comprise one of a dedicated remote control device associated with the second user device, a universal remote control device, a smart phone, a mobile phone, a tablet computer, a gaming console, a portable gaming device, a laptop computer, or a desktop computer.

Merely by way of example, in some embodiments, the audio-based set of commands might comprise a plurality of unique tones that are each mapped to a corresponding one of the one or more functions. The plurality of unique tones, in some instances, might comprise a plurality of audible tones. In some cases, emitting the generated audio-based set of commands might comprise emitting, with the one or more speakers of the first user device, the plurality of audible tones at a sound pressure level below auditory threshold (i.e., below 0 dB at 1 kHz). According to some embodiments, the plurality of unique tones might comprise at least one of a plurality of infra-sonic tones or a plurality of ultra-sonic tones. In some cases, the audio-based set of commands might comprise one or more masking audible tones overlaid on each of the at least one of the plurality of infra-sonic tones or the plurality of ultra-sonic tones. The one or more masking audible tones might be unrelated or unassociated with any functions of the second user device.

In yet another aspect, a user device having remote control functionality might be provided. The user device might comprise one or more speakers, at least one processor, and a non-transitory computer readable medium in communication with the at least one processor. The computer readable medium might have encoded thereon computer software comprising a set of instructions executable by the at least one processor to control operation of the user device. The set of instructions might comprise instructions for receiving user input indicating user selection of one or more functions to be performed by a second user device and instructions for generating a first set of commands, based at least in part on the received user input. The set of instructions might further comprise instructions for generating an audio-based set of commands, based at least in part on the first set of commands and instructions for emitting, with the one or more speakers, the generated audio-based set of commands for instructing the second user device to perform the one or more functions.

In some embodiments, the user device might comprise one of a dedicated remote control device associated with the second user device, a universal remote control device, a smart phone, a mobile phone, a tablet computer, a gaming console, a portable gaming device, a laptop computer, or a desktop computer.

In still another aspect, a user device might comprise one or more microphones, at least one processor, and a non-transitory computer readable medium in communication with the at least one processor. The computer readable medium might have encoded thereon computer software comprising a set of instructions executable by the at least one processor to control operation of the user device. The set of instructions might comprise instructions for receiving, with the one or more microphones, an audio-based set of commands emitted from one or more speakers of a second user device and instructions for converting the received audio-based set of commands into a first set of commands that causes one of the user device or a third user device to perform one or more functions.

According to some embodiments, the user device might comprise one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker. In some cases, the set of instructions might further comprise instructions for performing the one or more functions, based at least in part on the first set of commands.

In some embodiments, the user device might comprise an audio receiver that communicatively couples to the third user device, wherein the third user device might comprise one of a video communication device, a video calling device, an image capture device, a presence detection device, a video recording device, a video playback device, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker. The set of instructions might further comprise instructions for sending the first set of commands to the third user device, wherein the first set of commands causes the third user device to perform the one or more functions.

In another aspect, a system might comprise a first user device and a second user device. The first user device might comprise one or more speakers, at least one first processor, and a first non-transitory computer readable medium in communication with the at least one first processor. The first non-transitory computer readable medium might have encoded thereon computer software comprising a first set of instructions executable by the at least one first processor to control operation of the first user device. The second user device might comprise one or more microphones, at least one second processor, and a second non-transitory computer readable medium in communication with the at least one second processor. The second non-transitory computer readable medium might have encoded thereon computer software comprising a second set of instructions executable by the at least one second processor to control operation of the second user device.

The first set of instructions might comprise instructions for receiving user input indicating user selection of one or more functions to be performed by one of the second user device or a third user device and instructions for generating a first set of commands, based at least in part on the received user input. The first set of instructions might further comprise instructions for generating an audio-based set of commands, based at least in part on the first set of commands and instructions for emitting, with the one or more speakers, the generated audio-based set of commands for instructing the second user device to perform the one or more functions. The second set of instructions might comprise instructions for receiving, with the one or more microphones, the audio-based set of commands emitted from the one or more speakers of the first user device and instructions for converting the received audio-based set of commands into a second set of commands that causes one of the second user device or the third user device to perform the one or more functions.

Merely by way of example, in some embodiments, the audio-based set of commands might comprise a plurality of unique tones that are each mapped to a corresponding one of the one or more functions. The plurality of unique tones, in some instances, might comprise a plurality of audible tones. In some cases, emitting the generated audio-based set of commands might comprise emitting, with the one or more speakers of the first user device, the plurality of audible tones at a sound pressure level below auditory threshold (i.e., below 0 dB at 1 kHz). According to some embodiments, the plurality of unique tones might comprise at least one of a plurality of infra-sonic tones or a plurality of ultra-sonic tones. In some cases, the audio-based set of commands might comprise one or more masking audible tones overlaid on each of the at least one of the plurality of infra-sonic tones or the plurality of ultra-sonic tones. The one or more masking audible tones might be unrelated or unassociated with any functions of the second user device.

Various modifications and additions can be made to the embodiments discussed without departing from the scope of the invention. For example, while the embodiments described above refer to particular features, the scope of this invention also includes embodiments having different combination of features and embodiments that do not include all of the above described features.

### BRIEF DESCRIPTION OF THE DRAWINGS

A further understanding of the nature and advantages of particular embodiments may be realized by reference to the remaining portions of the specification and the drawings, in which like reference numerals are used to refer to similar components. In some instances, a sub-label is associated with a reference numeral to denote one of multiple similar components. When reference is made to a reference numeral without specification to an existing sub-label, it is intended to refer to all such multiple similar components.

FIGS. 1A and 1B are block diagrams illustrating various systems for providing audio-based remote control functionality, in accordance with various embodiments.

FIGS. 2A-2D are block diagrams illustrating systems having various apparatuses that may be controlled via audio-based remote control functionality, in accordance with various embodiments.

FIGS. 3A-3D are schematic diagrams illustrating audio-based communications between user devices, in accordance with various embodiments.

FIG. 4 is a process flow diagram illustrating a method of providing audio-based remote control functionality, in accordance with various embodiments.

FIGS. 5A and 5B are process flow diagrams illustrating various methods of receiving audio-based remote control commands and performing functions based on commands that are based at least in part on the received audio-based remote control commands, in accordance with various embodiments.

FIG. 6 is a generalized schematic diagram illustrating a computer system, in accordance with various embodiments.

FIG. 7 is a block diagram illustrating a networked system of computers, which can be used in accordance with various embodiments.

### DETAILED DESCRIPTION OF CERTAIN EMBODIMENTS

While various aspects and features of certain embodiments have been summarized above, the following detailed description illustrates a few exemplary embodiments in further detail to enable one of skill in the art to practice such embodiments. The described examples are provided for illustrative purposes and are not intended to limit the scope of the invention.

In the following description, for the purposes of explanation, numerous specific details are set forth in order to provide a thorough understanding of the described embodiments. It will be apparent to one skilled in the art, however, that other embodiments of the present invention may be practiced without some of these specific details. In other instances, certain structures and devices are shown in block diagram form. Several embodiments are described herein, and while various features are ascribed to different embodiments, it should be appreciated that the features described with respect to one embodiment may be incorporated with other embodiments as well. By the same token, however, no single feature or features of any described embodiment should be considered essential to every embodiment of the invention, as other embodiments of the invention may omit such features.

Unless otherwise indicated, all numbers used herein to express quantities, dimensions, and so forth used should be understood as being modified in all instances by the term “about.” In this application, the use of the singular includes the plural unless specifically stated otherwise, and use of the terms “and” and “or” means “and/or” unless otherwise indicated. Moreover, the use of the term “including,” as well as other forms, such as “includes” and “included,” should be considered non-exclusive. Also, terms such as “element” or “component” encompass both elements and components comprising one unit and elements and components that comprise more than one unit, unless specifically stated otherwise.

Features Provided by Various Embodiments

Various embodiments provide tools and techniques for providing audio-based remote control of consumer electronics devices (in some cases, consumer electronics devices that do not have or do not require dedicated remote controllers). By foregoing a dedicated remote controller or dedicated remote control device, the cost of consumer electronics devices can be lowered. Further, this allows the user to interface with the consumer electronics devices in simpler fashion. In general, however, audio-based remote control functionality allows for omni-directional communication between devices that offer different channels of communication other than line-of-sight based remote control (e.g., infrared, etc., which may be blocked or obscured easily) or network based remote control (e.g., which might be susceptible to network drop-outs or fidelity issues, etc.).

Merely by way of example, some embodiments allow remote control functionality for a consumer electronics device that is audio-based.

Various methods for pairing are described in the '390 application, which has already been incorporated herein by reference in its entire for all purposes. Pairing might allow a consumer electronic device (whether with or without a dedicated remote control device) to communicate with a server over a network or to establish network communication so as to communicate with the server over the network. The server might provide the consumer electronic device with information regarding potential audio-based remote control devices (e.g., identification codes for such remote control devices and/or one of private or public keys for authentication between the consumer electronic device and the remote control devices, or the like). These methods, however, are intended to merely be illustrative, and are in no way intended to limit the scope of the various embodiments.

Pairing with Gesture or Voice Recognition

In some embodiments, a first user device (such as a consumer electronics (“CE”) device) might be connected to a display device, and/or might include a display device incorporated therein (i.e., in the case of a television or monitor, or the like). The first user device might display a list of Wi-Fi networks in the area. Using gesture and/or voice recognition, the first user device might receive user inputs (in the form of gesture and/or voice input) that indicate the user's selection of a network from among the list of Wi-Fi networks, and optionally may receive user inputs including a password for the selected network.

Once the device is connected to the Internet via the selected network, the device might receive information about potential audio-based remote control devices from the server and/or might receive one half of the authentication key (i.e., one of a public key or a private key). Meanwhile, a second user device (including, without limitation, a smart phone, tablet computer, and/or the like), which might serve as an audio-based remote control device, might be used to communicate with the server over the Internet or other network, and, in some cases, might utilize software application (“App”; including, but not limited to, a smartphone App, tablet computer App, and/or the like) to do so, in order to download an audio-based remote control app for controlling the consumer electronic device via audio-based commands, to download conversion software for converting regular commands into audio-based commands, and/or to download the other half of the authentication key (i.e., the other of the public key or the private key).

Once the App has been downloaded, the second user device may be used to issue audio-based commands or instructions to remotely control the first user device. These commands may include, without limitation, volume up, volume down, cursor movement, etc. The App may display controls on its screen that may be depressed or otherwise selected by the user, or the unit may take input via moving the remote control and using its motion sensor. The input may include gesture input via an image capture device (e.g., camera, etc.) from the second user device (e.g., smartphone or tablet computer, etc.). The input may also be taken via microphone from the second user device (e.g., smartphone or tablet computer, etc.). The image, video, or audio data may be interpreted in the second user device and commands may be sent to the first user device, or the raw image, video, or audio data may be sent to the first user device for processing. In some cases, where remote control is via the network, raw image, video, or audio data may be sent to a server (or distributed infrastructure elements in a cloud environment, such as the user devices described in detail in the '360 application (already incorporated by reference herein in its entirety for all purposes)) for processing.

In various embodiments, multiple user devices (including, without limitation, smart phones or tablet computers, etc.; similar to the second user device) may be paired with the first user device. This may be desirable if a family wants to be able to control a user device (e.g., a TV, media player, or gaming console) using one or more of these user devices.

Pairing without Gesture or Voice Recognition

In some embodiments, a first user device might display a personal identification number (“PIN”) or pairing code on a screen of a display device (which might be integrated with, or external to, the first user device), similar to the example described above. The first user device and a second user device (including, without limitation, a smartphone, a tablet computer, and/or the like) might be operational using a communication technology that allows pairing, including, but not limited to, Bluetooth™ technology, WiFi technology, or near field communication (“NFC”) technology.

Using the second user device (and more specifically, using an App for the smart phone, tablet computer, and/or the like), users might select connection with the first user device, e.g., by depressing or otherwise selecting a “connect” button, a pairing button, a link, and/or the like. The user then enters the PIN or pairing code that is displayed on the screen of the display device into the App running in the second user device. The two devices then use standard pairing protocols (including, but not limited to, Bluetooth™ protocols).

Once the devices are paired, the communication link might be used to setup the first user device. In an example, the first user device might scan for Wi-Fi networks, which are then communicated through the Bluetooth™ connection and displayed on the smartphone. The user selects one of the Wi-Fi networks from those displayed on the smartphone (and optionally enters a password for the selected Wi-Fi network). The first device then connects to the selected Wi-Fi network. The controlling device (i.e., the smartphone or second user device) might then send commands to the first user device via Bluetooth™ connection or through the Internet connection—selection of which may be determined by lowering latency, lowering power consumption, and/or based on which communication path is active/functional.

In the various embodiments, there is never a need to use a dedicated remote control (otherwise referred to herein as “remote controller” or “remote control device”). This is a key advantage for manufacturers of consumer electronics devices, because they can ship each device in a box, without shipping a dedicated remote control in the box, and the user can simply connect it to a display device, plug it in, and then is able to completely set it up and use it (i.e., without the dedicated remote control). Another advantage of these techniques includes the ability to remotely control the consumer electronics device via the Internet (by any paired user device), i.e., after the connection has been established using the second user device.

Further, referring to the examples above, the first user device and the second user device (e.g., smartphone or tablet computer) may communicate via a server in the cloud environment. This server may be able to tell the smartphone or tablet computer if the first user device is available or not, and it may be able to tell the first user device if there are devices connected to control it. When there is a device connected to control it, the first user device may respond by turning on the display, as an example.

Need to Pair at any Time

When a CE device ships without a dedicated remote control, it is desirable to always have the ability to pair the CE device with a controlling device, even if the CE device has already been paired. This is due to the fact that the controlling device may not always be present (e.g., in the case of a mobile phone or smart phone), the controlling device may also get lost, the controlling device may be replaced with a newer model, etc. In this type of scenario, the CE device would be in a dead-lock situation without the ability to re-pair itself to another controlling device.

There are several mechanisms that allow a device to be paired and re-paired at any time, which include the following: always allowing for the option to pair on a physical reboot of the device (for example, a device that no longer has a controlling device can be rebooted (e.g., using a physical button, a soft button, a switch, power reset, etc.), which automatically brings up a pairing option; providing a physical button, a soft button, a switch, and/or the like, on the CE device to enable triggering of pairing with another device (in this manner, if the controlling device is unavailable, another controlling device can always be setup by pressing the physical button, soft button, switch, and/or the like); allowing proximity detection of the controlling device to trigger pairing (for example, if a controlling device is not detected nearby, then the pairing option can automatically be displayed on the screen; examples of proximity can include making a Bluetooth or NFC connection with the controlling device or finding the controlling device on the same local network); and allowing for Internet-triggered re-pairing (in the case of a CE device that has already been connected to the Internet, a web-based interface to the CE device via a side channel such as TCP can be used to trigger pairing to another controlling device).

Preventing Unauthorized Pairings

With CE devices that do not ship with a dedicated remote control, it is also important to prevent pairing with unauthorized devices. This prevents authorized access and control of the CE device. There are many mechanisms for preventing unauthorized pairing. These include, but are not limited to, authentication of the controlling device and requiring physical proximity to enable pairing. For authentication of the controlling device, as part of the pairing process, information that makes the controlling device uniquely identifiable (for example, the MAC address) is stored on the CE device. The authentication information prevents unauthorized controlling devices to control the CE device. Requiring physical proximity to the CE device can prevent unauthorized pairings, as it presumes physical access to the CE device, which can deter many unauthorized pairings. Examples of methods that require physical proximity include, without limitation, pressing a button on the CE device to pair, using are wireless technique for pairing that requires proximity such as NFC or Bluetooth™.

Latency Minimization

Latency minimization is important. The second user device or controlling device (e.g., smartphone, tablet computer, etc.) may seek to select the lowest latency method for communicating with the first user device. This prioritization may be in the order as follows: peer-to-peer connection, e.g., Bluetooth™ or Wi-Fi adhoc (which represents a good case); connection on the same local subnet (wired or wireless) (which represents another good case); and connection using standard Internet routing, where routing and latency are unknown (which represents the worst case).

Gesture and Voice Recognition

In gesture recognition, there may be a key symbol that the camera is always looking for, e.g., an open hand. If that happens, it may be a trigger for a first device, e.g., a CE device, to take or receive user input (in the form of gesture input). This may cause the device to open its menu, make the display active, etc.

The same may apply to voice recognition, e.g., where a user may say a control phrase to trigger the menu to start or for the system to be activated to receive a directive, e.g., “Computer. Call Bob.” or “Computer. Watch TV.”

Audio-Based Remote Control Functionality

In some embodiments, an application running on a user device (e.g., remote control device, smart phone, tablet computer, or the like) might cause one or more speakers to produce tones that a computer or other user device can understand. In some cases, SSID and other commands might be sent as audible or tone-based commands. In some instances, keystrokes (in which every single key on a remote control device or user device is mapped to a unique tone) can be sent as a stand-alone audible or tone-based command, or can be embedded within one or more audible or tone-based commands. In some embodiments, a user might use typed input or voice input as the user input for generating the audible or tone-based commands. In some cases, the user might speak out a voice command either letter by letter or word by word, and the voice command input might be displayed on a screen (together with a request for the user to confirm the voice command input).

According to some embodiments, background noise should and sometimes must be considered. However, there is no need to worry about crosstalk like in voiceband modems (which are point-to-point). Because anyone can hear the audible command (in some cases), other devices might hear it as well, in which case it may be necessary to differentiate commands with respect to their audible characteristics. For example, in some aspects, a header might be included in the audible command signal, and unique identifiers might identify the sending device and/or the recipient device(s). In some cases, the unique identifiers might include manufacturer codes (to easily distinguish one brand of products from another when sending or receiving audible commands) or unique device identifiers (to allow for different devices made by the same manufacturer (or different manufacturers) to be easily distinguished). In some embodiments, a tone can be assigned by a user for each device to be controlled, and the control signal can be hidden within the tone.

In some instances, the one or more audible or tone-based commands can be designed to avoid annoying users, by generating audible or tone-based commands that correspond to musical cords or harmonics or cords, or the like. In some embodiments, based on psycho-acoustic theory or the like, certain sounds can be made to mask other sounds—i.e., signals can be hidden within signals. For example, annoying tones or sounds can be hidden under pleasant or non-annoying sounds. Spread-spectrum techniques or the like may be used to extract the hidden signals in the audible commands. In some cases, audible commands can be modulated to have low-volume audio, high-volume audio, different frequencies (either higher frequency or lower frequency), low amplitude signal levels, high amplitude signal levels, or the like, in some cases based at least in part on detected or measured ambient (or background) noise levels.

According to some embodiments, a control device with a microphone might communicatively couple to any user device to be controlled having certain ports (i.e., the control device is external to the user device to be controlled) to provide such user devices (to be controlled) with the capacity or capability to receive audible or tone-based commands and to perform functions based on the received audible or tone-based commands. In some cases, downloadable applications (“apps”) and controls might be downloaded to a controller user device (e.g., remote control device, smart phone, tablet computer, or the like), and such apps or controls might map inputs (e.g., hard buttons, soft buttons, other user input, or the like) on the controller user device with controls for the user device to be controlled. Such apps or controls can be used to generate the audible or tone-based commands for sending to the user devices to be controlled.

When the controller user device communicates with the user device to be controlled (whether only during the very first (i.e., initiation) communication, during each communication exchange, or during each communication session (having multiple communication exchanges)), an audible handshake might occur, in which both devices concurrently send out exchange information in audible command form, thereby setting up, or maintaining command links between, both devices.

In some embodiments, encryption may be used on the audible commands. In some cases, a public/private key pair may be used. For example, an app on the controller user device might be provided with a public key, while the device to be controlled might be provided with the corresponding private key. In alternative embodiments, the controller user device might be provided with a private key, while the device to be controlled might be provided with the corresponding public key. In such cases, the message or command might be signed, and the sender might be authenticated.

In some aspects, an app-based audible command remote controller for a smart phone, tablet computer, or the like might displace or replace dedicated remote control devices.

### Exemplary Embodiments

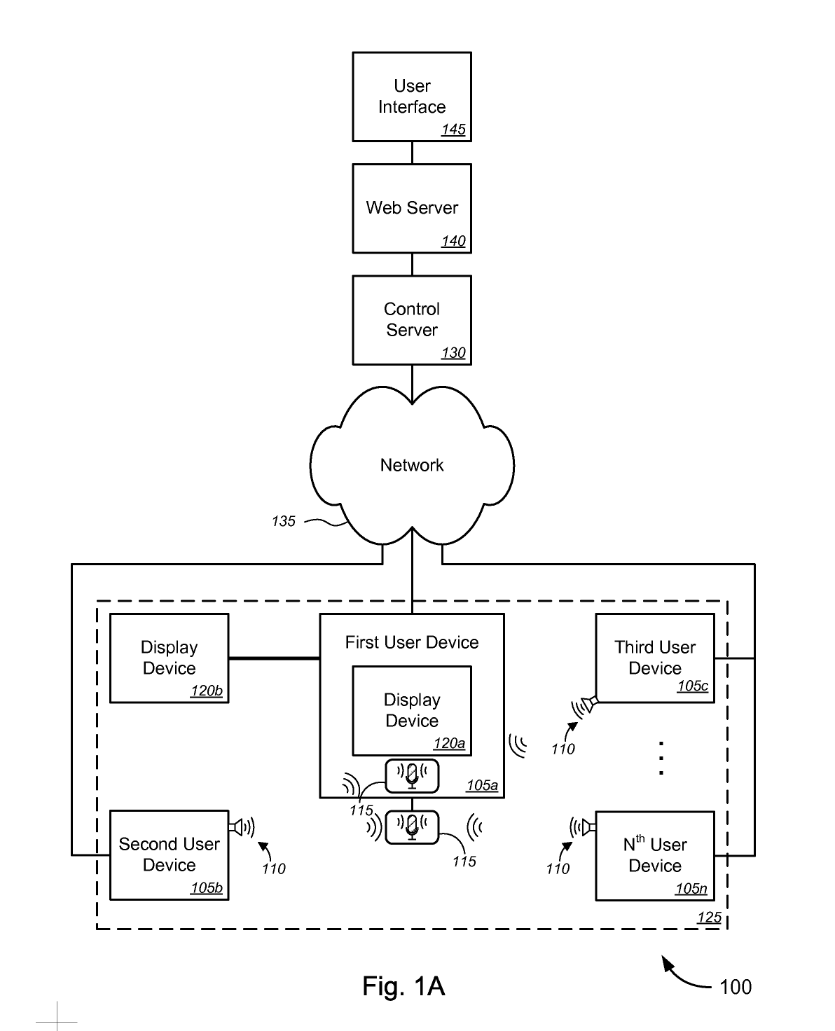

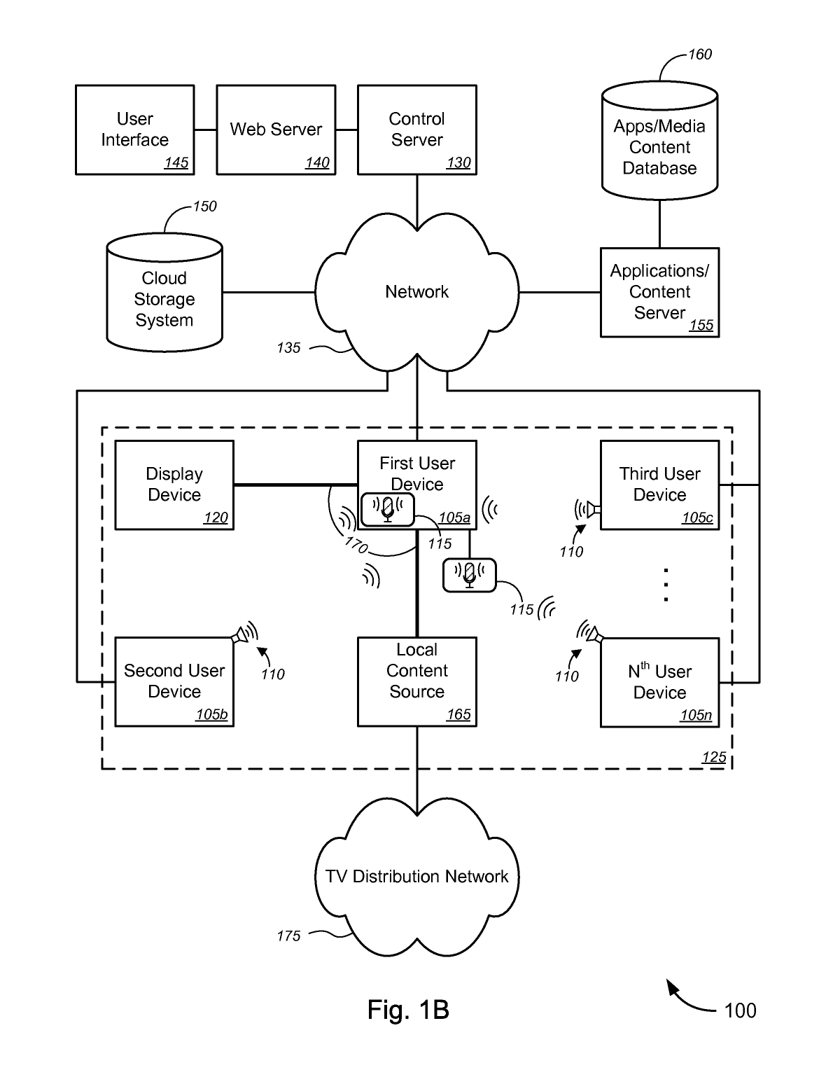

FIGS. 1-7 illustrate exemplary embodiments that can provide some or all of the features described above. The methods, systems, and apparatuses illustrated by FIGS. 1-7 may refer to examples of different embodiments that include various components and steps, which can be considered alternatives or which can be used in conjunction with one another in the various embodiments. The description of the illustrated methods, systems, and apparatuses shown in FIGS. 1-7 is provided for purposes of illustration and should not be considered to limit the scope of the different embodiments.

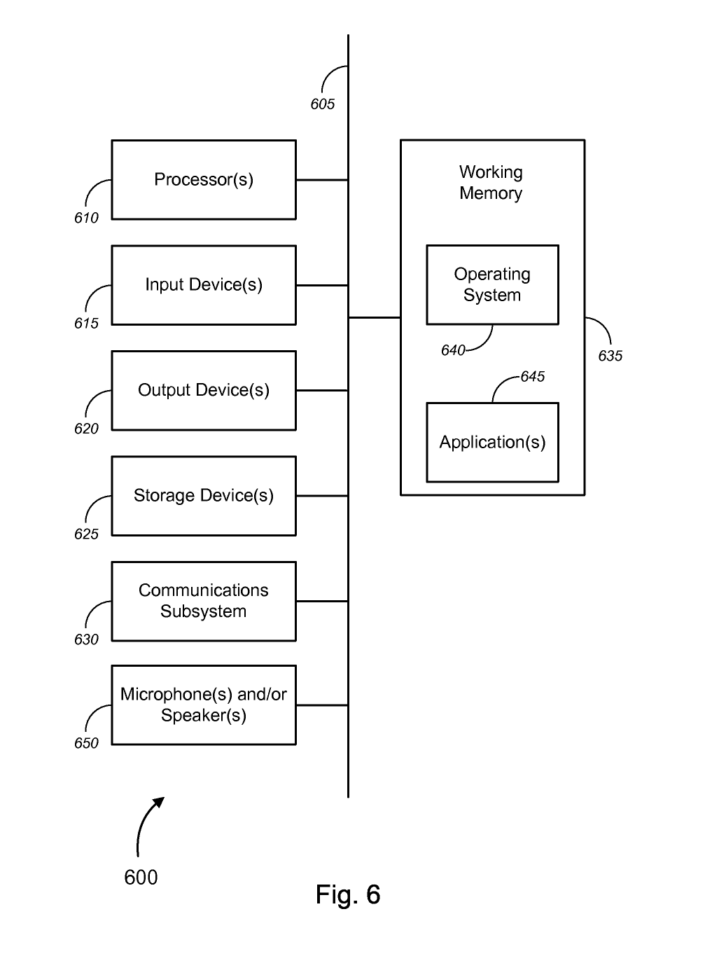

FIGS. 1A and 1B (collectively, “FIG. 1”) illustrate functional diagrams of various systems 100 for providing audio-based remote control functionality, in accordance with various embodiments. The skilled reader should note that the arrangement of the components illustrated in FIG. 1 is functional in nature, and that various embodiments can employ a variety of different structural architectures. Merely by way of example, one exemplary, generalized architecture for the system 100 is described below with respect to FIG. 6, but any number of suitable hardware arrangements can be employed in accordance with different embodiments.

In FIG. 1, system 100 might comprise a plurality of user devices 105, which might include, without limitation, any one or any combination of a video communication device, a video calling device, an image capture device, a presence detection device, a video recording device, a video playback device, a set-top box, an audio recording device, an audio playback device, a tablet computer, a laptop computer, a desktop computer, a toy vehicle, a toy aircraft, or a consumer electronic device sold without a dedicated remote controller. In some cases, the plurality of user devices 105 might also include, but is not limited to, a gaming console, a smart phone, a mobile phone, a portable gaming device, or a remote control device, and/or the like. The plurality of user devices 105 might include a first user device 105a, which might be a device intended to be controlled remotely, and second through N^{th} user devices 105b-105n, which might be devices intended to serve as (non-dedicated) remote controllers or remote control devices for the first user device 105a. In some embodiments, only the second user device 105b might be established as a remote controller for the first user device 105a. In alternative embodiments, any number of user devices among the second through N^{th} user devices 105b-105n might be established as remote controllers for the first user device 105a.

Herein, a “dedicated remote controller” or “dedicated remote control device” might refer to a remote controller that is packaged with a user device for which it controls, and is, in most cases, manufactured for that sole purpose. On the other hand, a “non-dedicated remote controller” or “non-dedicated remote control device” might refer to a remote controller that is sold separately from the device to be controlled, and is, in most cases, manufactured to also perform functions separate from, and unrelated to, remote control of said device to be controlled.

In particular embodiments, the first user device 105a might be or might include one of a video communication device, a video calling device, an image capture device, a presence detection device, a video recording device, a video playback device, a set-top box, an audio recording device, an audio playback device, a tablet computer, a laptop computer, a desktop computer, a toy vehicle, a toy aircraft, a gaming console, or a consumer electronic device sold without a dedicated remote controller, or any other suitable electronics device that requires user input. Each of the second through N^{th} user devices 105b-105n might be or might include one of a smart phone, a mobile phone, a tablet computer, a desktop computer, a laptop computer, a portable gaming device, or a remote control device (such as an original equipment manufacturer (“OEM”) “smart” remote control device or an aftermarket “smart” remote control device, etc.), or the like.

To establish one or more of the second through N^{th} user devices 105b-105n as remote controllers or remote control devices for the first user device 105a, each of the one or more of the second through N^{th} user devices 105b-105n might communicate with the control server 130 via network 135 (either via wired or wireless connection) in order to download the audio-based command conversion information for a particular first user device 105a to be controlled or audio-based command program (e.g., “app”). The process might, in some embodiments, further include the control server 130 communicating with the first user device 105a and/or the intermediate device 115, via network 135, to provide the first user device 105a and/or the intermediate device 115 with identification and/or authentication information about each of the one or more of the second through N^{th} user devices 105b-105n. For example, in some cases, the control server 130, after initiation of the process of enabling each of the one or more of the second through N^{th} user devices 105b-105n as an audio-based remote control device for the first user device 105a, might send a public key to each of the one or more of the second through N^{th} user devices 105b-105n and, at the same time, send a private key to the first user device 105a. The control server 130a, might also send to the one or more of the second through N^{th} user devices 105b-105n information about converting control signals for the first user device 105a into audio-based sets of commands for the first user device 105a or for the intermediate device 115. Alternatively, the one or more of the second through N^{th} user devices 105b-105n can download an audio-based remote control app from the control server 130 or associated database(s). According to some embodiments, network 135 might include at least one of an Ethernet network, a local area network (“LAN”), a wide area network (“WAN”), a wireless wide area network (“WWAN”), a virtual private network (“VPN”), an intranet, an extranet, the Internet, a public switched telephone network (“PSTN”), an infra-red network, or a radio frequency (“rf”) network, and/or the like. The user interface 145 hosted on a web server 140 might, in some cases, help the user to facilitate downloading of the appropriate audio-based command conversion information or audio-based remote control program (e.g., “app”).

System 100 might further comprise one or more display devices 120, which might include an incorporated or integrated display device 120a and/or an external display device 120b. In particular, the integrated display device 120a might be part of, or otherwise incorporated into, the first user device 105a, while the external display device 120b might be external to, but in communication with, the first user device 105a. In some embodiments, the integrated display device 120a might include, but is not limited to, an integrated touchscreen device, a removable display device (including touchscreen display and/or non-touchscreen display), and/or the like, while the external display device 120b might include, without limitation, an external monitor, a television (including, without limitation, a cable television (“TV”), a high-definition (“HD”) TV, an Internet Protocol (“IP”) TV, a satellite TV, and/or the like), and/or any other suitable external display device.

In various embodiments, the first user device 105a might be located at customer premises 125, and, in some embodiments, each of at least one of the second through N^{th} user devices 105b-105n might also be located in the same customer premises 125. In some alternative embodiments, one or more of the second through N^{th} user devices 105b-105n might be located outside the customer premises 125, but within audible reception range (at any of infra-sonic, sonic (i.e., within range of human hearing), ultrasonic, at a sound pressure level below audible threshold, at a sound pressure level above audible threshold, and/or the like) of the first user device 105 or an intermediate audio-reception device 115.

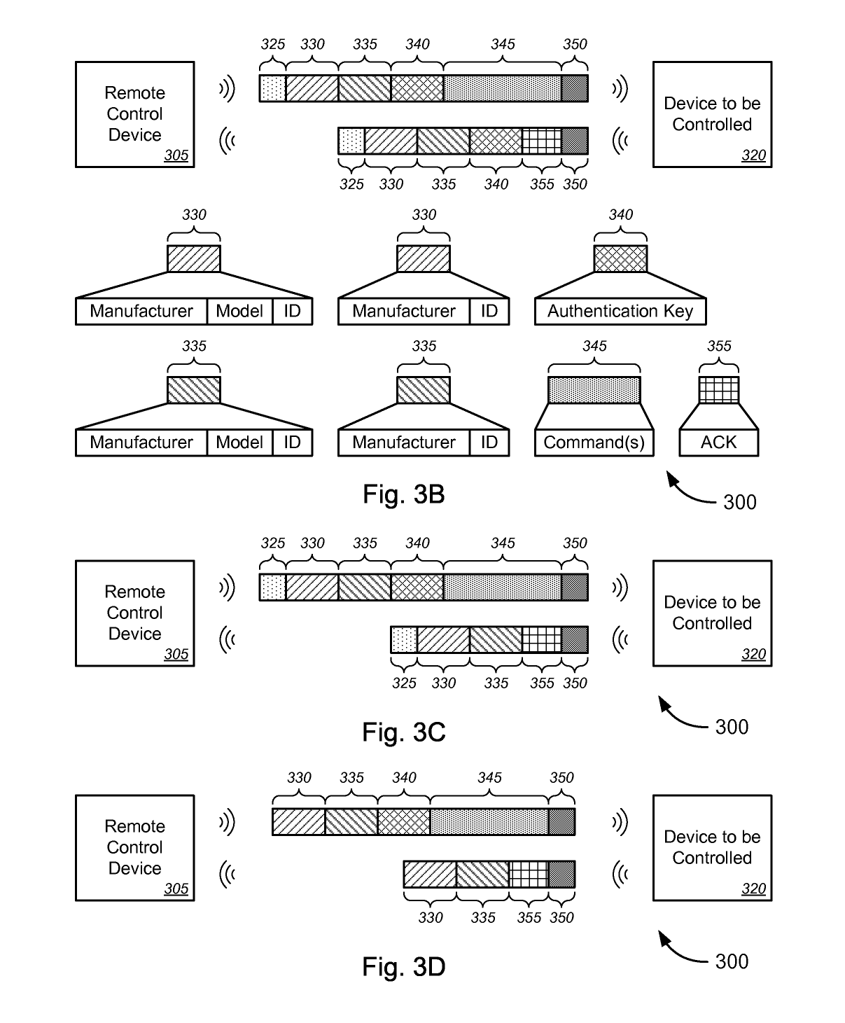

In some embodiments, once established as remote controllers for the first user device 105a, any of the second through N^{th} user devices 105b-105n might be configured to provide remote control functionality emitting audio-based commands via speaker(s) 110 to the first user device 105a, in a manner similar to that as described below with respect to FIG. 3B-3D.

In some embodiments, as shown in FIG. 1B, system 100 might further comprise a local content source 165 (which, in some embodiments, might include a set-top box (“STB”) and/or the like), and high-definition (“HD”) data cables 170 (or any other suitable data transmission media). In some cases, the HD data cables 170 might include, without limitation, high-definition multimedia interface (“HDMI”) cables or any other suitable HD data cables. The first user device 105a, as shown in FIG. 1, might be configured to provide pass-through audio and/or video from a local content source 165 to display device 120 (e.g., using data cables 170). Merely by way of example, in some embodiments, a HD data input port (e.g., a HDMI input port) in the first user device 105a allows HD signals to be input from the corresponding local content source 165, and a HD data output port (e.g., a HDMI output port) in the first user device 105a allows HD signals to be output from the first user device 105a to the corresponding display device 120 (e.g., monitor or TV, which might include, but is not limited to, an IPTV, a HDTV, a cable TV, or the like). The output HD signal may, in some cases, be the input HD signal modified by the user device 105a. Local content source 165 might be any suitable local content source. As described herein, a local content source is any device that provides an audio or video stream to a display device (and thus can include, without limitation, a cable STB, a satellite STB, an IPTV STB, devices that generate video and/or audio, and/or acquire video and/or audio from other sources, such as the Internet, and provide that video/audio to a display device, and/or the like). Hence, when situated functionally inline between a local content source and a display device, the first user device 105a can receive an audiovisual stream output from the local content source, modify that audiovisual stream in accordance with the methods described in the '182 patent, and provide the (perhaps modified) audiovisual stream as input to the display device 120. In some embodiments, the first user device 105a, local content source 165, display device 120, and any of second through N^{th} user devices 105b-105n might be located at customer premises 125, while, in some other embodiments, some or all of second through N^{th} user devices 105b-105n might be located outside customer premises 125 (yet within audible range of the first user device 105a).

According to some embodiments, system 100 might further comprise one or more access points (not shown), each of which might be located in proximity to or in the customer premises 125. The access point(s) can allow wireless communication between each user device 105 and network 135. (Of course, a user device 105 might also have a wired connection to an access point, router, residential gateway, etc., such as via an Ethernet cable, which can provide similar communication functionality.) In some cases (as shown), each user device 105 might be communicatively coupled to network 135 (via either wired or wireless connection), without routing through any access points. In some cases, wired or wireless access to network 135 allows user device 105 to obtain profiles from cloud storage system 150 and/or applications/media content from applications/content server 155 and applications/media content database 160 independent of the corresponding local content source 165, which is in communication with a television (“TV”) distribution network 175 (either via wireless connection or via wired connection). In some cases (not shown), TV distribution network 175 (which could be, for example, a cable television distribution network, a satellite television distribution network, an IPTV distribution network, and/or the like) might be communicatively coupled with content server 155, and thus local content source 165 might obtain media content from content server 155 and media content database 160 independently of user device 105a. Alternatively or in addition, the television distribution network 175 might be communicatively coupled to other content servers and/or other media content sources (not shown).

In this manner, the first user device 105a, in some embodiments, can overlay the input signal from the corresponding local content source 165 with additional media content to produce an augmented output HD signal to the corresponding display device 120 via data cables 170. This functionality allows for supplemental content (which may be associated with the media content accessed by the local content source 165 for display on display device 120) to be accessed and presented using the first user device 105a, in some cases, as a combined presentation on the display device 120, which may be one of an overlay arrangement (e.g., a picture-in-picture (“PIP”) display, with the supplemental content overlaid on the main content), a split screen arrangement (with the supplemental content adjacent to, but not obscuring any portion of the main content), a passive banner stream (with non-interactive supplemental content streaming in a banner(s) along one or more of a top, bottom, left, or right edge of a display field in which the main content is displayed on display device 120), and/or an interactive banner stream (with interactive supplemental content streaming in a banner(s) along one or more of a top, bottom, left, or right edge of a display field in which the main content is displayed on display device 120). Herein, examples of interactive supplemental content might include, without limitation, content that when streamed in a banner can be caused to slow, stop, and/or replay within the banner, in response to user interaction with the content and/or the banner (as opposed to passive banner streaming, in which information is streamed in a manner uncontrollable by the user). The interactive supplemental content that is streamed in the banner may, in some instances, also allow the user to invoke operations or functions by interacting therewith; for example, by the user highlighting and/or selecting the supplemental content (e.g., an icon or still photograph of a character, actor/actress, scene, etc. associated with the main content), links for related webpages, links to further content stored in media content database 160, or operations to display related content on display device 120 and/or second through N^{th} user devices 105b-105n may be invoked.

In some instances, first user device 105a might detect the presence and/or proximity of one or more of the second through N^{th} user devices 105b-105n (which may or may not be associated with the user), and might (based on user profile information associated with the user that is stored, e.g., in cloud storage system 150) automatically send supplemental media content via wireless link 110 (directly from first user device 105a or indirectly via an access point (not shown)) for display on a display screen(s) of the one or more of the second through N^{th} user devices 105b-105n. In one non-limiting example, a user associated with the first user device 105a might have established a user profile stored in cloud storage system 150 that indicates a user preference for any and all supplemental content for movies and television programs to be compiled and displayed on one or more of the second through N^{th} user devices 105b-105n (including, but not limited to, a tablet computer, a smart phone, a laptop computer, and/or a desktop computer, etc.) concurrent to display of the movie or television program being displayed on display device 120. In such a case, when a movie is playing on display device 120 broadcast or streamed via local content source 165 from content server 175 and media content database 155 (and/or from some other content server and some other media content source) via network 175, first user device 105a accesses supplemental content (if available) from content server 175 and media content database 155 via network 135, and sends the supplemental content to the on one or more of the second through N^{th} user devices 105b-105n (e.g., user's tablet computer and/or smart phone, and/or the like) via wireless link(s) 110. For example, bios of actors, actresses, and/or crew might be sent to the user's smart phone for display on the screen thereof, while schematics of machines, weapons, robots, tools, etc. associated with the movie or television show might be sent to and displayed on the user's tablet computer, behind the scenes videos or information, news/reviews associated with the main content, and/or music videos associated with the main content may also be sent to the user's smart phone and/or tablet computer, and so on.

According to some embodiments, the detection of the presence of one or more of the second through N^{th} user devices 105b-105n by the first user device 105a might allow identification of a user and thus access of profiles and/or content associated with the user's account, regardless of whether the first user device 105a is owned by and/or associated with the user. This presence detection functionality is described in detail in the '279 application (already incorporated herein by reference in its entirety for all purposes).

In some embodiments, the first user device 105a might be a video capture device, and one or more of the second through N^{th} user devices 105b-105n might provide virtual remote control of the video capture device over the network, as described in detail herein and as described in detail in the '263 application (already incorporated herein by reference in its entirety for all purposes). In some aspects, the first user device 105a might serve as a distributed infrastructure element in a cloud-computing system, and one or more of the second through N^{th} user devices 105b-105n might provide virtual remote control of the distributed infrastructure element over the network, as described in detail herein and as described in detail in the '360 application (already incorporated herein by reference in its entirety for all purposes). According to some embodiments, the first user device 105a might provide functionality for enabling or implementing video mail capture, processing, and distribution, one or more of the second through N^{th} user devices 105b-105n might provide virtual remote control of the distributed infrastructure element over the network, as described in detail herein and as described in detail in the '499 application (already incorporated herein by reference in its entirety for all purposes).

Although some of the embodiments described above refer to media content delivery, processing, distribution, or otherwise, through the first user device 105a, and remote control of first user device 105a using one or more of the second through N^{th} user devices 105b-105n, the various embodiments need not deliver, process, or distribute media content through the first user device 105a. Rather, in some alternative embodiments, other functionalities of the first user device 105a may be remotely controlled using one or more of the second through N^{th} user devices 105b-105n. Take, for example, the case where the first user device 105a comprises a toy vehicle or toy aircraft. In such instances, the one or more of the second through N^{th} user devices 105b-105n might be established as remote controllers for the toy vehicle or toy aircraft, and thus are provided with functionality to control the movement and other functions (e.g., any of lights, sounds, camera functions, and/or the like) of the toy vehicle or toy aircraft. Likewise, with other embodiments of the first user device 105a, other functionalities, including, but not limited to, any camera functionalities, any settings controls, any data transfer preferences and controls, any communications settings or controls, and/or the like, may be controlled by any one or more of the second through N^{th} user devices 105b-105n that have been established as remote controllers for these embodiments of the first user device 105a.

Further, the system 100, according to the various embodiments allows for minimizing latency between user input (using any of the second through N^{th} user device 105b-105n) and actual remote control of functionalities of the first user device 105a. In some embodiments, to minimize latency, the system might first attempt to establish a peer-to-peer connection between the first user device 105a and at least one of the second through N^{th} user devices 105b-105n, in a manner as described in detail with respect to the '304 application. If that fails, then the system might attempt to establish connection via a local subnet. If such attempt fails, then the system might attempt to establish connection via the Internet.

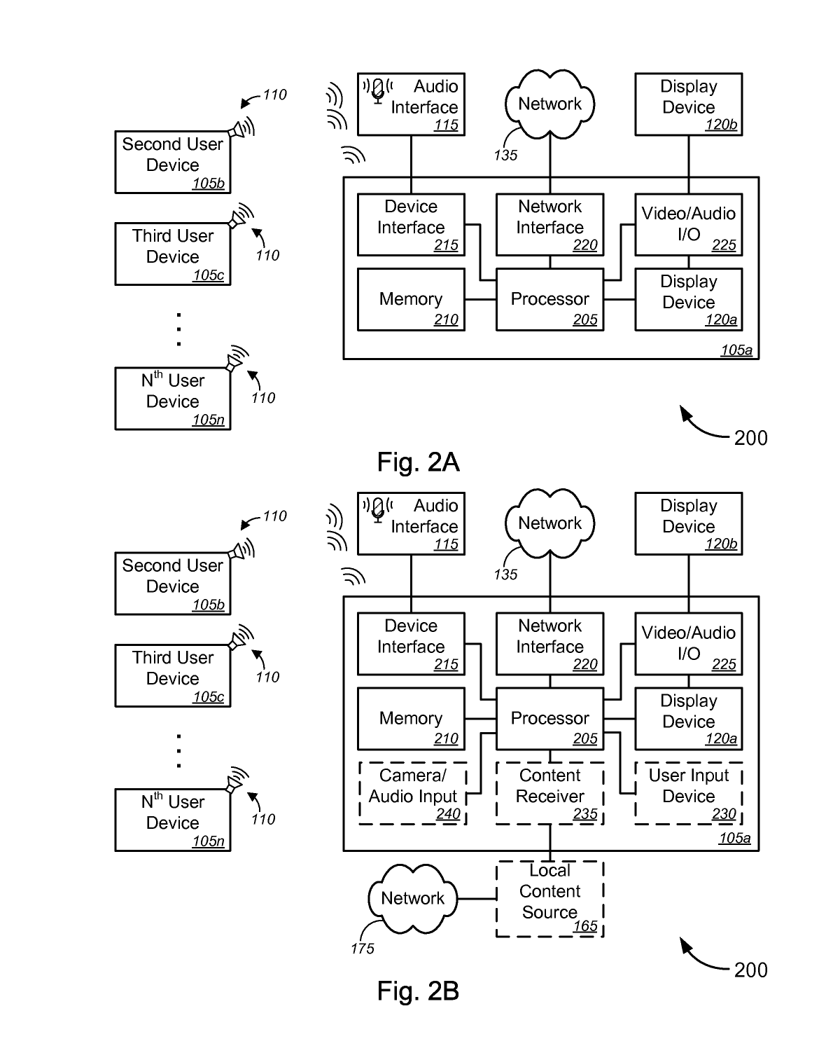

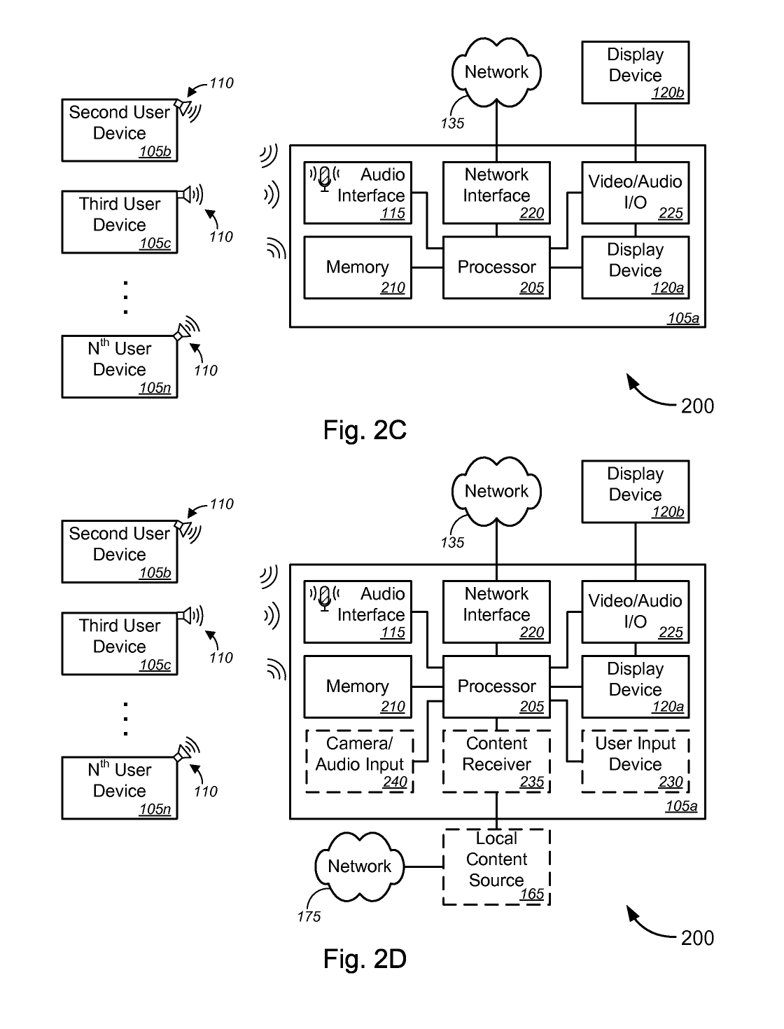

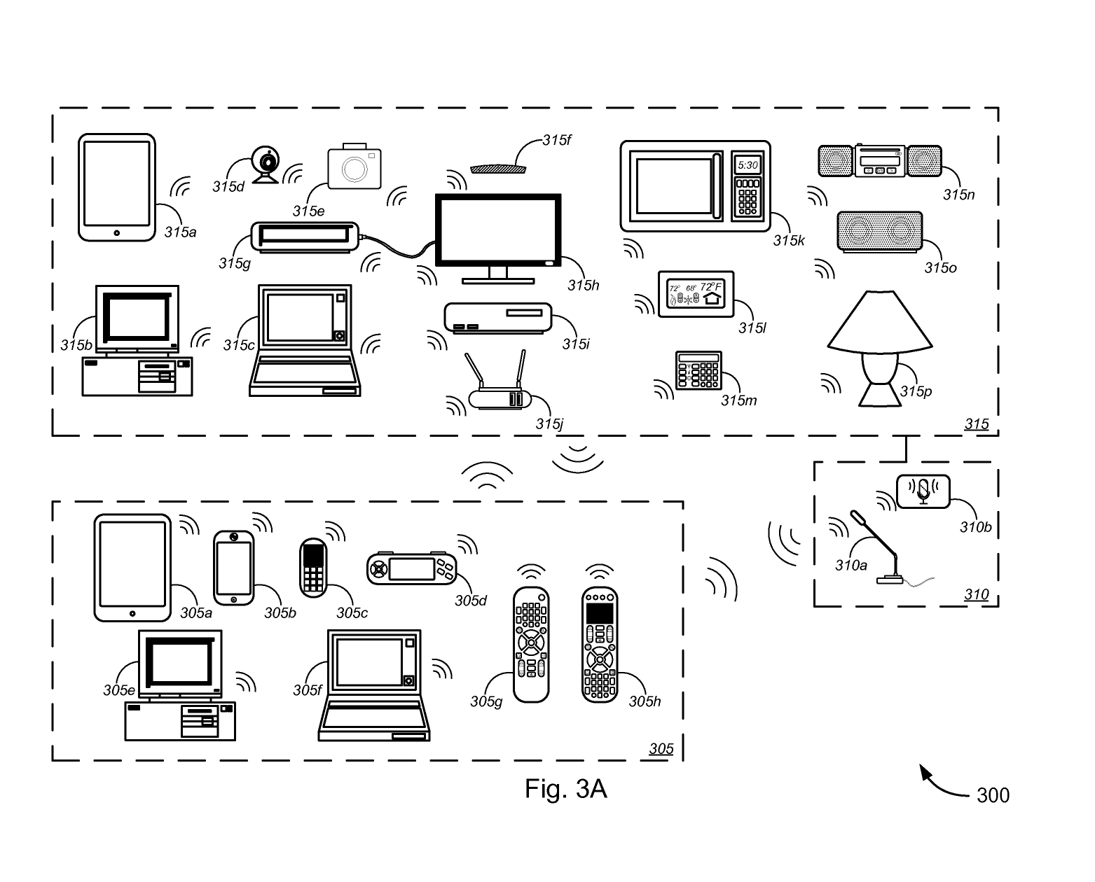

With reference to FIGS. 2A-2D (collectively, “FIG. 2”)—are block diagrams illustrating systems 200 having various apparatuses that may be controlled via audio-based remote control functionality, in accordance with various embodiments, system 200 is shown comprising elements or components of system 100 shown in FIG. 1, with particular focus on components or subcomponents of the first user device 105a.

In the embodiment shown in FIG. 2A, system 200 might comprise the first user device 105a, at least one of second through N^{th} user devices 105b-105n, one or more speakers 110 that allow audio-based commands/information to be communicated between the first user device 105a and the at least one of second through N^{th} user devices 105b-105n, integrated display device 120a and/or an external display device 120b, and network 135. System 200 may or may not include other components of system 100 shown in FIGS. 1A and 1B, which are not shown in FIG. 2A to avoid complicating the illustrated example. In some embodiments, the first user device 105a might comprise one or more processors 205, one or more memory devices 210, one or more device interfaces 215, and one or more network interfaces 220. The one or more device interfaces 215 might be configured to establish wireless or wired communication with an audio interface device or intermediate device 115, which in turn communicates via audio-based commands/information with at least one of second through N^{th} user devices 105b-105n. The wireless communication might comprise peer-to-peer wireless communication, or any other suitable types of wireless communication. In that regard, the wireless communication might include, without limitation, infra-red (“IR”) communication, ultraviolet (“UV”) communication, a WiMax communication, a WWAN communication, Bluetooth™ communication, WiFi communication, communication using any other suitable protocol of the 802.11 suite of protocols, cellular communication, near field communication (“NFC”), and/or the like.

In some instances, the first user device 105a might further comprise an integrated display device 120a. In other cases, the first user device 105a might further comprise one or more video/audio input/output (“I/O”) devices 225 that may be configured to communicatively couple to one or more external display devices 120b. In some cases, the one or more video/audio input/output (“I/O”) devices 225 might be communicatively coupled to one or more external display devices 120b via HD data cables (such as, but not limited to, HD data cables 170 described above). According to some aspects, the first user device 105a might comprise both the integrated display device 120a and the one or more video/audio input/output (“I/O”) devices 225.

In the embodiment shown in FIG. 2B, system 200 might further comprise a first user device 105a further including at least one of one or more user input devices 230, one or more content receivers 235, and/or one or more cameras/audio inputs 240. The one or more user input devices 230 might include, but are not limited to, mice and other pointing devices, touchpads and/or touchscreens, keyboards (e.g., numeric and/or alphabetic), buttons, switches, and/or the like. The one or more cameras 240 might include, without limitation, motion capture devices or other suitable image/video capture devices. The audio input devices might include, but is not limited to, microphones or other suitable audio capture devices. The one or more content receivers 235 might each be communicatively coupled with local content source 165, and in turn communicatively coupled with network 175. First user device 105a, second through N^{th} user devices 105b-105n, and other components of system 200 in FIG. 2 might otherwise function in a similar manner as described above with respect to first user device 105a, second through N^{th} user devices 105b-105n, and other components of system 200 in FIG. 1.

FIGS. 3A-3D (collectively, “FIG. 3”) illustrate audio-based communications between user devices, in accordance with various embodiments. The skilled reader should note that the user devices (and components thereof) illustrated in FIG. 3 are provided merely for illustration, and that various embodiments can employ any of a variety of user devices or types of user devices that are designed, configured, or modified to allow for audio-based remote control functionality consistent with, but not limited to, the embodiments described herein.

In the embodiment of FIG. 3A, system 300 might comprise one or more first user devices 305, one or more second user devices 310, and one or more third user devices 315. The one or more first user devices 305, which may perform the role of an audio-based remote control device, might include, without limitation, one or more tablet computers 305a, one or more smart phones 305b, one or more mobile phones 305c, one or more portable gaming devices 305d, one or more desktop computers 305e, one or more laptop computers 305f, one or more dedicated remote control devices 305g, one or more universal remote control devices 305h, and/or the like. The one or more second user devices 310, which may perform the role of an intermediate audio-based command device interface, might include, but is not limited to, one or more microphones 310a, one or more audio-receiving (and transmitting) devices 310b, and/or the like. The one or more third user devices 315, which may perform the role of a device to be controlled, might include, without limitation, one or more tablet computers 315a, one or more desktop computers 315b, one or more laptop computers 315c, one or more webcams 315d, one or more image capture devices 315e, one or more video communication devices 315f, one or more video recording/playback devices or set-top box 315g, one or more televisions 315h, one or more gaming consoles 315i, one or more network interface devices 315j, one or more home appliances 315k, one or more thermostats 3151, one or more residential or commercial security control devices 315m, one or more audio recording/playback devices 315n, one or more external speakers 315o, one or more lighting devices 315p, and/or the like. Although not shown, the one or more third user devices might further include, but are not limited to, a door-lock mechanism, a door opening/closing mechanism, a window opening/closing mechanism, a skylight opening/closing mechanism, a window covering adjustment system, and/or the like.

According to some embodiments, the audio-based remote control device (e.g., a first user device 305) might receive user input indicating user selection of one or more functions to be performed by a particular device that the user would like to control. The audio-based remote control device might generate a first set of commands, based at least in part on the received user input, might generate an audio-based set of commands, based at least in part on the first set of commands, and might emit (via one or more speakers either integrated in the audio-based remote control device or external to the device yet communicatively coupled to it) the generated audio-based set of commands for instructing the particular device to be controlled to perform the one or more functions.

In the embodiments in which the device to be controlled has both a microphone (or other audio receiving device) and a conversion device that is configured to convert audio-based commands into commands that the device requires (or understands) to initiate performance of one or more functions, such device might receive the audio-based set of commands emitted from the one or more speakers of the audio-based remote control device (i.e., the first user device 305), and might convert the received audio-based set of commands into a first set of commands that cause the device to be controlled to perform the one or more functions associated with the commands. In some cases, the device to be controlled might send an acknowledgement to the remote control device to indicate that the first set of commands have been received. In such cases, the device to be controlled would have to comprise one or more speakers and the remote control device would have to comprise one or more microphones (or other audio receiving device).

In some embodiments, if a device to be controlled (e.g., a third user device 315) either does not have a microphone or other audio receiving device, does not have a conversion device that is configured to convert audio-based commands into commands that the device requires (or understands) to initiate performance of one or more functions, or both, then an intermediate device (e.g., a second user device 310) may be communicatively coupled to the device to be controlled. Such intermediate device (e.g., the second user device 310) may receive the audio-based set of commands emitted from the one or more speakers of the audio-based remote control device (i.e., the first user device 305), and might convert the received audio-based set of commands into a first set of commands that might cause a device to be controlled to perform the one or more functions associated with the commands. In some cases, the intermediate device might communicatively couple to the device to be controlled via wired connection (including, but not limited to, wired connection via universal serial bus (“USB”) connection, or other electrical connection, or the like) or via wireless connection (including, without limitation, local area network (“LAN”) connection, Bluetooth™ connection, WiFi connection, WiMax connection, any other network connection operating under any of the IEEE 802.11 suite of protocols, and/or the like).

The intermediate device (e.g., the second user device 310) might send the first set of commands to the device to be controlled (e.g., the third user device 315) via one or more (or any) of the wired or wireless connections mentioned above. The device to be controlled (e.g., the third user device 315) might receive the first set of commands from the intermediate device (e.g., the second user device 310), and might perform the one or more functions based at least in part on the first set of commands. In some cases, the device to be controlled might send an acknowledgement, via the intermediate device, to the remote control device to indicate that the first set of commands have been received. In such cases, the intermediate device would have to comprise one or more speakers and the remote control device would have to comprise one or more microphones (or other audio receiving device).

With reference to FIGS. 3B-3D, which illustrate non-limiting embodiments of audio-based communications between a remote control device 305 (i.e., the first user device 305) and a device to be controlled 320 (which is one of the second user device 310 or the third user device 315). In the embodiment of FIG. 3B, the remote control device 305 might send an audio-based set of commands, which might include, without limitation, a header portion 325 (or a “listen to me” command or a “heads-up” command, or the like), a “to” or recipient identification portion 330 (which is necessary where there are multiple devices within range of the remote control device that may receive and process the commands), a “from” or sender identification portion 335 (which is necessary where there are multiple remote control devices available, and where authentication alone is not sufficient), an authentication key portion 340 (which might include one of a private key or a public key), a command portion 345 (which includes the actual commands that are converted to an audio signal), and an end portion 350 (which indicates the end-of-file or end of transmission of the command sequence and/or the set of commands), or the like. Once the audio-based commands have been received, the device to be controlled 320, in some embodiments, might send an acknowledgement or other information. The acknowledgement or other information might include, without limitation, a header portion 325 (or a “listen to me” command or a “heads-up” command, or the like), a “to” or recipient identification portion 330 (which is necessary where there are multiple devices within range of the remote control device that may receive and process the commands), a “from” or sender identification portion 335 (which is necessary where there are multiple remote control devices available, and where authentication alone is not sufficient), an authentication key portion 340 (which might include the other of the private key or the public key), a data portion 355, and an end portion 350 (which indicates the end-of-file or end of transmission of the command sequence and/or the set of commands), or the like. In some embodiments, some or all of the header portion 325, the “to” or recipient identification portion 330, the “from” or sender identification portion 335, the authentication key portion 340, the command portion 345, the data portion 355, and the end portion 350 might be encrypted.

For acknowledgement only messages, the data portion 355 might include the acknowledgement message that has been converted into an audio signal. For other information, the data portion 355 might include such other information. In some cases, such other information might include, but is not limited to, information regarding media content (e.g., for media presentation devices such as, but not limited to, tablet computers, desktop computers, laptop computers, webcams, image capture devices, video communications devices, video recording/playback devices, set-top boxes, televisions, gaming consoles, audio playback devices, and/or the like). In some instances, such other information might further or alternatively include, without limitation, information regarding status of operation or other status information (e.g., for devices such as, but not limited to, network communication devices (to indicate network connection status or the like), home appliances (to indicate whether the appliance is on or off, at what settings the appliance is currently set, what time is on any timer countdowns, any other alerts, reminders for next step in recipe or user program, message to change components (e.g., filters, bulbs, panels, motors, etc.), and/or the like), thermostat (to indicate current temperature, current humidity, desired or set temperature, desired or set humidity, mode (e.g., heating, cooling, circulate, etc.), weather forecast, and/or the like), security system (to indicate whether the stay or away settings are on or off, whether there have been any alerts or breaches, whether network or emergency communications lines are operational or not, and/or the like), external speaker (to indicate whether the battery is low, the volume settings, audio output settings (e.g., fade, balance, bass, etc.), network connection settings, and/or the like), lighting systems (to indicate whether certain lights are on or off, whether bulbs should be changed, temperature, luminance, etc.), door/window/skylight opening/closing devices (to indicate whether the door/window/skylight is fully open, partially open, or closed, whether batteries should be changed (if not plugged into an electrical outlet), and/or the like), automated window covering devices (to indicate whether a door/window/skylight is fully covered, partially covered, or fully uncovered, whether batteries should be changed (if not plugged into an electrical outlet), and/or the like), and/or the like.

Merely by way of example, in some aspects, each of the “to” and “from” portions 330 and 335 might include information indicating the manufacturer of each device (i.e., device 305 or 320), information indicating the model of each device (i.e., device 305 or 320), the identification code of each device (i.e., device 305 or 320), and/or the like. Alternatively, each of the “to” and “from” portions 330 and 335 might include information indicating the manufacturer of each device (i.e., device 305 or 320), the identification code of each device (i.e., device 305 or 320), and/or the like, without information indicating the model of each device (i.e., device 305 or 320).

In some alternative embodiments, e.g., as shown in the embodiment of FIG. 3C, the response (or other communications) from device to be controlled 320 might include, without limitation, a header portion 325 (or a “listen to me” command or a “heads-up” command, or the like), a “to” or recipient identification portion 330 (which is necessary where there are multiple devices within range of the remote control device that may receive and process the commands), a “from” or sender identification portion 335 (which is necessary where there are multiple remote control devices available, and where authentication alone is not sufficient), a data portion 355, and an end portion 350 (which indicates the end-of-file or end of transmission of the command sequence and/or the set of commands), or the like, without an authentication key portion 340 (especially where only acknowledgement or non-sensitive information is being sent back to the remote control device).

According to some embodiments, in both signals from/to the remote control device 305 and to/from the device to be controlled 320 might leave out the header portion 325. Although not shown, in some cases, the “from” portion 335 might be left out of the signals, particularly where there is only one remote control device 305 or where the devices to be controlled 320 are limited to receiving commands from one or one type of audio-based remote control device (which is preset (i.e., out of the box) or set later by the user (and subject to change by the user), or the like).

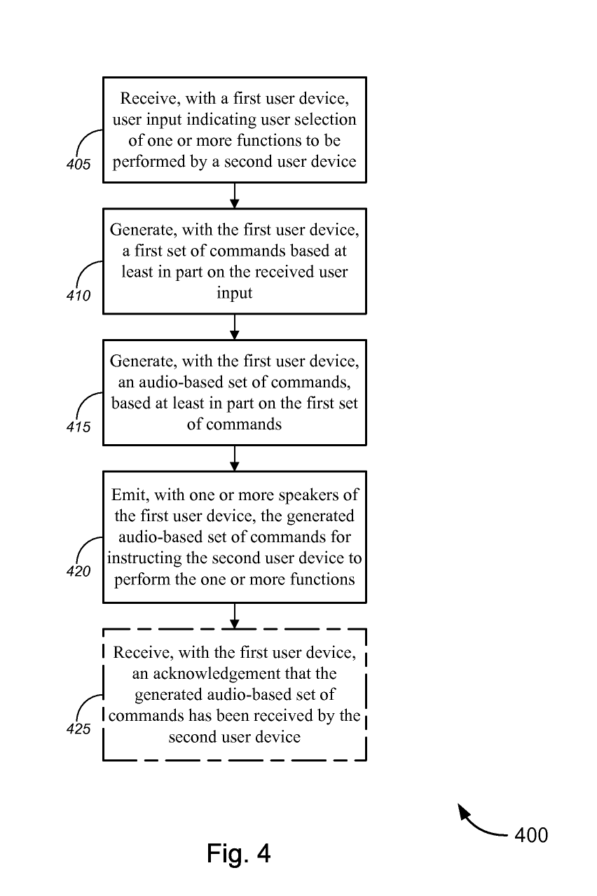

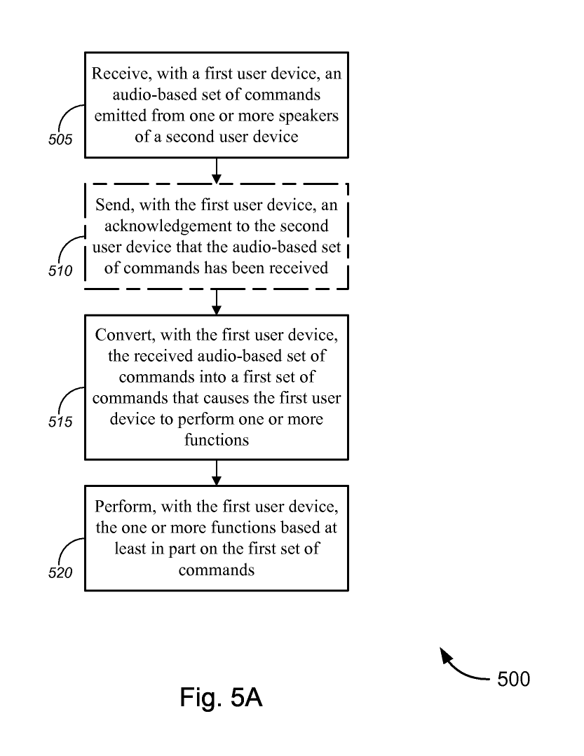

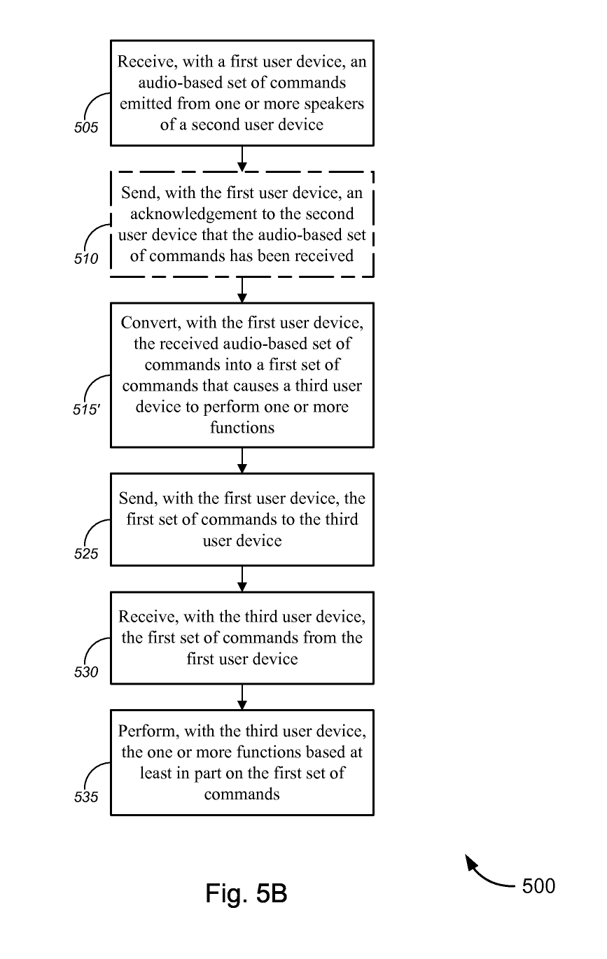

FIGS. 4 and 5 illustrate various methods for providing audio-based remote control functionality. In particular, FIG. 4 is a process flow diagram illustrating a method 400 of providing audio-based remote control functionality, in accordance with various embodiments. FIGS. 5A and 5B (collectively, “FIG. 5”) are process flow diagrams illustrating various methods 500 of receiving audio-based remote control commands and performing functions based on commands that are based at least in part on the received audio-based remote control commands, in accordance with various embodiments. While the techniques and procedures are depicted and/or described in a certain order for purposes of illustration, it should be appreciated that certain procedures may be reordered and/or omitted within the scope of various embodiments. Moreover, while the method illustrated by FIG. 4 and/or FIG. 5 can be implemented by (and, in some cases, are described below with respect to) the system 100 of FIG. 1 (or components thereof), system 200 of FIG. 2 (or components thereof), or system 300 of FIG. 3 (or components thereof), such methods may also be implemented using any suitable hardware implementation. Similarly, while the system 100 of FIG. 1 (and/or components thereof), system 200 of FIG. 2 (and/or components thereof), or system 300 of FIG. 3 (or components thereof), can operate according to any of the methods illustrated by FIG. 4 and/or FIG. 5 (e.g., by executing instructions embodied on a computer readable medium), the system 100, system 200, and/or system 300 can also operate according to other modes of operation and/or perform other suitable procedures.

Turning to FIG. 4, which is from the perspective of an audio-based remote control device, method 400 might comprise, at block 405, receiving, with a first user device, user input indicating user selection of one or more functions to be performed by a second user device. Here, the first user device might be an audio-based remote control device, and might include one of a dedicated remote control device associated with the second user device, a universal remote control device, or a mobile user device, or the like. The mobile user device might include one of a smart phone, a mobile phone, a tablet computer, a gaming console, a portable gaming device, a laptop computer, or a desktop computer, or the like. The second user device might be a device to be controlled by the audio-based remote control device, and might include one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker, or the like.

At block 410, method 400 might comprise generating, with the first user device, a first set of commands, based at least in part on the received user input. Method 400 might further comprise generating, with the first user device, an audio-based set of commands, based at least in part on the first set of commands (block 415). According to some embodiments, the user input might comprise one of a typed user input or a voice user input that does not match any of a preselected group of commands, and generating at least one of the first set of commands or the audio-based set of commands might comprise embedding the one of typed user input or voice user input as message data in the at least one of the first set of commands or the audio-based set of commands. For example, the user might speak or type in an e-mail address, which the first user device might embed (as message data or the like) in the first set of commands and/or the audio-based set of commands. Likewise, the user might speak or type in a password or pass code, which might be embedded as message data in a similar way.

Merely by way of example, in some embodiments, generating the audio-based set of commands, based at least in part on the first set of commands, might comprise generating, with the first user device, an audio-based set of commands, based at least in part on the first set of commands, using forward error control (“FEC”) code. In some cases, the FEC code might comprise one of repetition code, binary convolutional code, block code, low density parity check code, a combination of these codes, and/or the like. Method 400, at block 420, might comprise emitting, with one or more speakers of the first user device, the generated audio-based set of commands for instructing the second user device to perform the one or more functions.

In some embodiments, the method might further comprise modulating, with the first user device, the audio-based set of commands using orthogonal frequency-division multiplexing (“OFDM”), prior to emitting the generated audio-based set of commands. Alternatively or additionally, the method might comprise modulating, with the first user device, the audio-based set of commands using spreading sequence modulation, prior to emitting the generated audio-based set of commands. In some cases, the method might further comprise modifying, with the first user device, frequency range of sound of the generated audio-based set of commands based on at least one of frequency range of the one or more speakers or sampling rate used with the one or more speakers.

In some embodiments, the audio-based set of commands might include, without limitation, a plurality of unique tones that are each mapped to a corresponding one of the one or more functions. In some cases, the plurality of unique tones might include a plurality of audible tones. In some instances, each audible tone might be chosen or designed to be pleasant to a broad selection of a population (e.g., people who are resident to a geographic region or location in which the audio-based system is being sold and implemented). In some cases, emitting the generated audio-based set of commands might comprise emitting, with the one or more speakers of the first user device, the plurality of audible tones at a sound pressure level below auditory threshold, which is frequency dependent and dependent on an individual's sense of hearing. For the purposes herein, the auditory threshold is taken to be the auditory threshold at 1 kHz of an average person, which is about 0 dB. Hence a sound pressure level below the auditory threshold is below 0 dB (herein also referred to as being “sub-audible”).

According to some embodiments, the plurality of unique tones comprise at least one of a plurality of infra-sonic tones (i.e., tones at frequencies below the “normal” range of hearing for humans or below the “normal” limit of human hearing; typically lower than 20 Hz, or the like) or a plurality of ultra-sonic tones (i.e., tones at frequencies exceeding the “normal” range of hearing for humans or above the “normal” limit of human hearing; typically greater than 20 kHz, or the like). In some cases, the audio-based set of commands might include, without limitation, one or more masking audible tones overlaid on each of the at least one of the plurality of infra-sonic tones or the plurality of ultra-sonic tones. In some embodiments, the one or more masking audible tones might also be overlaid on sub-audible tones or tones that would be audible if not for being overlaid with the masking tones (herein also referred to as being “masked tones”). The one or more masking audible tones may, in some instances, be unrelated or unassociated with any functions of the second user device. In other words, the masking audible tones are merely emitted to mask the command tones (which may be infra-sonic, ultra-sonic, sub-audible, and/or masked tones, or the like) and/or to provide an audible notification to a user(s) that a command has been sent from an audio-based remote control device to one or more devices intended to be controlled, or the like.

According to some embodiments, the audio-based set of commands might comprise a packet field, a packet header field, and a message field, and the method might further comprise performing, with the first user device and prior to emitting the generated audio-based set of commands, a cyclic redundancy check (“CRC”) on the audio-based set of commands, by appending a CRC check value for protecting at least one of the packet field, the packet header field, the message field, and/or the like. In some cases, the audio-based set of commands might comprise at least one of a source address, a destination address, a target device type, a target device model number, and/or the like.

In some embodiments, the plurality of unique tones might comprise a plurality of audible tones that are harmonics of each other (which, according to some embodiments, might optionally be achieved by using OFDM). In some cases, the plurality of unique tones might comprise one or more musical cords. In some instances, the plurality of unique tones might comprise two or more unique tones that are classified into audibly distinguishable groups, each group being associated with a user device separate from other user devices associated with other groups. For example, one set of tones might be associated with a television, while a second set of tones might be associated with a video conferencing device in communication with the television, while a third set of tones might be associated with a media content source, and so on. The different groups of unique tones would allow the user to audibly distinguish the sounds (e.g., to hear if the correct type of command is being sent). In some embodiments, the plurality of unique tones might comprise one or more tones that are correlated with at least one of phonetic sound of a command, meaning of a command, and/or evoked sense of a command, or the like. For example, phonetic sound of a command might include, without limitation, a combination of tones that approximate words (e.g., for the letter “A,” a combination of tones is generated to approximate the “A” sound; for word “Input,” a combination of tones is generated to approximate the “Input” sound; and so on). Evoked sense of a command or meaning of a command might comprise sounds that correlate with a message, and might include, but is not limited to, increasing volume and/or frequency to approximate a rising sound (e.g., question at the end of a sentence, etc.), generate sound to approximate an impulse to correspond to an “OFF” command, and/or the like. In some cases, the plurality of unique tones might comprise one or more tones each having at least one pattern embedded therein, wherein each tone, although audibly indistinguishable to a human, is distinguishable by a receiver from a combination of pattern and tone. In a non-limiting example, the generated tone might sound like the letter “A,” but the pattern (which might be a command sequence for instructing a television to perform one or more functions) hidden under the “A” sound is undetectable to a human, but can be distinguished by the second user device (e.g., using spread spectrum techniques or the like). In other words, the second user device might distinguish between an “A” sound with the background signal mixed in by the first user device and an “A” sound spoken by a human (regardless of how identical the sounds of the “A” spoken by the human and the “A” generated by the first user device).

In some aspects, at optional block 425, method 400 might comprise receiving, with the first user device, an acknowledgement message or notification that the generated audio-based set of commands has been received by the second user device. In some instances, the method might further comprise encrypting, with the first user device, the audio-based set of commands, prior to emitting the generated audio-based set of commands. As described above, a public/private key pair may be used. For example, the first user device (i.e., controller) might be provided with a public key, while the second user device (i.e., device to be controlled) might be provided with the corresponding private key. In alternative embodiments, the first user device (i.e., controller) might be provided with a private key, while the second user device (i.e., device to be controlled) might be provided with the corresponding public key. In such cases, the message or command might be signed, and the sender might be authenticated.

The method, in some embodiments, might further comprise measuring, with a microphone of the first user device, background noise level prior to emitting the generated audio-based set of commands. In such embodiments, emitting the generated audio-based set of commands might be performed based at least in part on a determination that the measured background noise level does not conflict with the generated audio-based set of commands when emitted (i.e., to avoid collisions or potential collisions, or the like). In some cases, the method might further comprise adjusting, with the first user device, volume of the one or more speakers based at least in part on the measured background noise level. For example, in a smartphone, volume of transmitted signal may be adjusted based on how much background noise the smartphone detects with its microphone(s).

In some instances, the second user device might respond to the emitted generated audio-based set of commands with one of an audible acknowledgement (“ACK”) or an audible negative ACK (“NACK”). Herein, the NACK might be sent by the second user device when a decoding error or other errors occur. In some cases, the method might further comprise adjusting, with the first user device, volume of the one or more speakers in response to one of receiving NACK, not receiving ACK, volume level of ACK, volume level of NACK from the second user device, and/or the like.

We now turn to FIG. 5, which is from the perspective of a receiver of audio-based commands. In FIG. 5, at block 505, method 500 might comprise receiving, with a first user device, an audio-based set of commands emitted from one or more speakers of a second user device. At optional block 510, method 500 might comprise sending, with the first user device, an acknowledgement to the second user device that the audio-based set of commands has been received. The processes at blocks 505 and 510 are equally applicable to the embodiments of FIGS. 5A and 5B.

Here, the first user device might be a device to be controlled by an audio-based remote control device, and might include one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker, or the like. The second user device might be an audio-based remote control device, and might include one of a dedicated remote control device associated with the second user device, a universal remote control device, or a mobile user device, or the like. The mobile user device might include one of a smart phone, a mobile phone, a tablet computer, a gaming console, a portable gaming device, a laptop computer, or a desktop computer, or the like.

As described above with respect to FIG. 4, in some embodiments, the audio-based set of commands might include, without limitation, a plurality of unique tones that are each mapped to a corresponding one of the one or more functions. In some cases, the plurality of unique tones might include a plurality of audible tones. In some instances, each audible tone might be chosen or designed to be pleasant to a broad selection of a population (e.g., people who are resident to a geographic region or location in which the audio-based system is being sold and implemented). In some cases, emitting the generated audio-based set of commands might comprise emitting, with the one or more speakers of the first user device, the plurality of audible tones at a sound pressure level below auditory threshold, which is frequency dependent and dependent on an individual's sense of hearing. For the purposes herein, the auditory threshold is taken to be the auditory threshold at 1 kHz of an average person, which is about 0 dB. Hence a sound pressure level below the auditory threshold is below 0 dB (herein also referred to as being “sub-audible”).

According to some embodiments, the plurality of unique tones comprise at least one of a plurality of infra-sonic tones (i.e., tones at frequencies below the “normal” range of hearing for humans or below the “normal” limit of human hearing; typically lower than 20 Hz, or the like) or a plurality of ultra-sonic tones (i.e., tones at frequencies exceeding the “normal” range of hearing for humans or above the “normal” limit of human hearing; typically greater than 20 kHz, or the like). In some cases, the audio-based set of commands might include, without limitation, one or more masking audible tones overlaid on each of the at least one of the plurality of infra-sonic tones or the plurality of ultra-sonic tones. In some embodiments, the one or more masking audible tones might also be overlaid on sub-audible tones or tones that would be audible if not for being overlaid with the masking tones (herein also referred to as being “masked tones”). The one or more masking audible tones may, in some instances, be unrelated or unassociated with any functions of the second user device. In other words, the masking audible tones are merely emitted to mask the command tones (which may be infra-sonic, ultra-sonic, sub-audible, and/or masked tones, or the like) and/or to provide an audible notification to a user(s) that a command has been sent from an audio-based remote control device to one or more devices intended to be controlled, or the like.

FIG. 5A illustrates embodiments having an integrated audio-based command receiver/microphone. Method 500, at block 515, might comprise converting, with the first user device, the received audio-based set of commands into a first set of commands that causes the first user device to perform one or more functions. According to some embodiments, the user input, upon which the audio-based set of commands is based, might comprise one of a typed user input or a voice user input that does not match any of a preselected group of commands, and the one of typed user input or voice user input as message data might be embedded in the audio-based set of commands. For example, the user might speak or type in an e-mail address, which the first user device might embed (as message data or the like) in the first set of commands and/or the audio-based set of commands. Likewise, the user might speak or type in a password or pass code, which might be embedded as message data in a similar way. Accordingly, converting the received audio-based set of commands into the first set of commands might comprise extracting the password or pass code from the message data that is embedded in the audio-based set of commands.

Merely by way of example, in some embodiments, the audio-based set of commands might have been generated using forward error control (“FEC”) code. In some cases, the FEC code might comprise one of repetition code, binary convolutional code, block code, low density parity check code, a combination of these codes, and/or the like. Accordingly, converting the received audio-based set of commands into the first set of commands might comprise determine whether FEC code was used in generating the audio-based set of commands, and if so, which one of repetition code, binary convolutional code, block code, low density parity check code, a combination of these codes, and/or the like was used. Converting the received audio-based set of commands might comprise converting into the first set of commands based at least in part on the determined one of repetition code, binary convolutional code, block code, low density parity check code, a combination of these codes, and/or the like.

In some cases, the audio-based set of commands might have been modulated using OFDM, spreading sequence modulation, and/or the like. In such cases, converting the received audio-based set of commands into the first set of commands might comprise determining which type of modulation was used, and converting accordingly. In a similar manner, because frequency range of sound of the generated audio-based set of commands might have been modified based on at least one of frequency range of the one or more speakers or sampling rate used with the one or more speakers, converting the received audio-based set of commands into the first set of commands might comprise determining how the audio-based set of commands has been modified, determining whether it is necessary to further modify the set of commands when converting into the first set of commands, and converting accordingly.

According to some embodiments, converting the received audio-based set of commands into the first set of commands might comprise checking the CRC check value that is appended on the audio-based set of commands for protecting at least one of the packet field, the packet header field, the message field, and/or the like. If it is determined that the audio-based set of commands is valid based on the CRC check, then the method proceeds to block 520. Otherwise, a notification indicating an error in the audio-based set of commands might be sent back to the second user device (not shown); in some cases, a NACK may be sent back to the second user device, e.g., to indicate a decoding error to other errors have occurred.

In some embodiments, converting the received audio-based set of commands into the first set of commands might comprise determining whether the audio-based set of commands is encrypted, and if so, decrypting the audio-based set of commands. In some cases, private-public key pairs may be used for decryption.

Method 500 might further comprise performing, with the first user device, the one or more functions, based at least in part on the first set of commands (block 520).

FIG. 5B illustrates embodiments in which an external audio-based command receiver/microphone (which, in some cases, is embodied in its own device) communicatively couples to a device to be controlled and converts received audio-based commands into commands that such a device to be controlled understands. At block 515′, method 500 might comprise converting, with the first user device, the received audio-based set of commands into a first set of commands that causes a third user device (which is communicatively coupled to the first user device) to perform one or more functions. Method 500, at block 525, might comprise sending, with the first user device, the first set of commands to the third user device. Method 500 might further comprise receiving, with the third user device, the first set of commands from the first user device (block 530) and performing, with the third user device, the one or more functions, based at least in part on the first set of commands (block 535).

FIG. 6 provides a schematic illustration of one embodiment of a computer system 600 that can perform the methods provided by various other embodiments, as described herein, and/or can function as a first user device (i.e., device to be controlled), second through N^{th} user devices (i.e., remote controller devices), control server, web server, and/or the like. It should be noted that FIG. 6 is meant only to provide a generalized illustration of various components, of which one or more (or none) of each may be utilized as appropriate. FIG. 6, therefore, broadly illustrates how individual system elements may be implemented in a relatively separated or relatively more integrated manner.

The computer system 600 is shown comprising hardware elements that can be electrically coupled via a bus 605 (or may otherwise be in communication, as appropriate). The hardware elements may include one or more processors 610, including without limitation one or more general-purpose processors and/or one or more special-purpose processors (such as digital signal processing chips, graphics acceleration processors, and/or the like); one or more input devices 615, which can include, without limitation, a mouse, a keyboard, a keypad, a touchscreen display, one or more buttons, one or more switches, and/or the like; and one or more output devices 620, which can include without limitation a display device, a touchscreen display, a printer, one or more light emitting devices, an audio speaker, and/or the like.

The computer system 600 may further include (and/or be in communication with) one or more storage devices 625, which can comprise, without limitation, local and/or network accessible storage, and/or can include, without limitation, a disk drive, a drive array, an optical storage device, a solid-state storage device such as a random access memory (“RAM”) and/or a read-only memory (“ROM”), which can be programmable, flash-updateable, and/or the like. Such storage devices may be configured to implement any appropriate data stores, including, without limitation, various file systems, database structures, and/or the like.

The computer system 600 might also include a communications subsystem 630, which can include, without limitation, a modem, a network card (wireless or wired), an infra-red communication device, a wireless communication device and/or chipset (such as a Bluetooth™ device, an 802.11 device, a WiFi device, a WiMax device, a WWAN device, cellular communication facilities, etc.), and/or the like. The communications subsystem 630 may permit data to be exchanged with a network (such as the network described below, to name one example), with other computer systems, and/or with any other devices described herein. In many embodiments, the computer system 600 will further comprise a working memory 635, which can include a RAM or ROM device, as described above.

The computer system 600 also may comprise software elements, shown as being currently located within the working memory 635, including an operating system 640, device drivers, executable libraries, and/or other code, such as one or more application programs 645, which may comprise computer programs provided by various embodiments, and/or may be designed to implement methods, and/or configure systems, provided by other embodiments, as described herein. Merely by way of example, one or more procedures described with respect to the method(s) discussed above might be implemented as code and/or instructions executable by a computer (and/or a processor within a computer); in an aspect, then, such code and/or instructions can be used to configure and/or adapt a general purpose computer (or other device) to perform one or more operations in accordance with the described methods.

A set of these instructions and/or code might be encoded and/or stored on a computer readable storage medium, such as the storage device(s) 625 described above. In some cases, the storage medium might be incorporated within a computer system, such as the system 600. In other embodiments, the storage medium might be separate from a computer system (i.e., a removable medium, such as a compact disc, etc.), and/or provided in an installation package, such that the storage medium can be used to program, configure, and/or adapt a general purpose computer with the instructions/code stored thereon. These instructions might take the form of executable code, which is executable by the computer system 600 and/or might take the form of source and/or installable code, which, upon compilation and/or installation on the computer system 600 (e.g., using any of a variety of generally available compilers, installation programs, compression/decompression utilities, etc.) then takes the form of executable code.

It will be apparent to those skilled in the art that substantial variations may be made in accordance with specific requirements. For example, customized hardware (such as programmable logic controllers, field-programmable gate arrays, application-specific integrated circuits, and/or the like) might also be used, and/or particular elements might be implemented in hardware, software (including portable software, such as applets, etc.), or both. Further, connection to other computing devices such as network input/output devices may be employed.

As mentioned above, in one aspect, some embodiments may employ a computer system (such as the computer system 600) to perform methods in accordance with various embodiments of the invention. According to a set of embodiments, some or all of the procedures of such methods are performed by the computer system 600 in response to processor 610 executing one or more sequences of one or more instructions (which might be incorporated into the operating system 640 and/or other code, such as an application program 645) contained in the working memory 635. Such instructions may be read into the working memory 635 from another computer readable medium, such as one or more of the storage device(s) 625. Merely by way of example, execution of the sequences of instructions contained in the working memory 635 might cause the processor(s) 610 to perform one or more procedures of the methods described herein.

According to some embodiments, system 600 might further comprise one or more microphones and/or one or more speakers 650. In some cases, the one or more microphones 650 might be incorporated in (or might otherwise be one of) the input device(s) 615. Likewise, in some instances, the one or more speakers 650 might be incorporated in (or might otherwise be one of) the input device(s) 620, and might be the same as or different from the audio speaker as mentioned above. The output device(s) 620 might, in some embodiments, further include one or more monitors, one or more TVs, and/or one or more display screens, or the like.

The terms “machine readable medium” and “computer readable medium,” as used herein, refer to any medium that participates in providing data that causes a machine to operate in a specific fashion. In an embodiment implemented using the computer system 600, various computer readable media might be involved in providing instructions/code to processor(s) 610 for execution and/or might be used to store and/or carry such instructions/code (e.g., as signals). In many implementations, a computer readable medium is a non-transitory, physical, and/or tangible storage medium. Such a medium may take many forms, including, but not limited to, non-volatile media, volatile media, and transmission media. Non-volatile media includes, for example, optical and/or magnetic disks, such as the storage device(s) 625. Volatile media includes, without limitation, dynamic memory, such as the working memory 635. Transmission media includes, without limitation, coaxial cables, copper wire, and fiber optics, including the wires that comprise the bus 605, as well as the various components of the communication subsystem 630 (and/or the media by which the communications subsystem 630 provides communication with other devices). Hence, transmission media can also take the form of waves (including, without limitation, radio, acoustic, and/or light waves, such as those generated during radio-wave and infra-red data communications).

Common forms of physical and/or tangible computer readable media include, for example, a floppy disk, a flexible disk, a hard disk, magnetic tape, or any other magnetic medium, a CD-ROM, any other optical medium, punch cards, paper tape, any other physical medium with patterns of holes, a RAM, a PROM, an EPROM, a FLASH-EPROM, any other memory chip or cartridge, a carrier wave as described hereinafter, or any other medium from which a computer can read instructions and/or code.

Various forms of computer readable media may be involved in carrying one or more sequences of one or more instructions to the processor(s) 610 for execution. Merely by way of example, the instructions may initially be carried on a magnetic disk and/or optical disc of a remote computer. A remote computer might load the instructions into its dynamic memory and send the instructions as signals over a transmission medium to be received and/or executed by the computer system 600. These signals, which might be in the form of electromagnetic signals, acoustic signals, optical signals, and/or the like, are all examples of carrier waves on which instructions can be encoded, in accordance with various embodiments of the invention.

The communications subsystem 630 (and/or components thereof) generally will receive the signals, and the bus 605 then might carry the signals (and/or the data, instructions, etc. carried by the signals) to the working memory 635, from which the processor(s) 605 retrieves and executes the instructions. The instructions received by the working memory 635 may optionally be stored on a storage device 625 either before or after execution by the processor(s) 610.

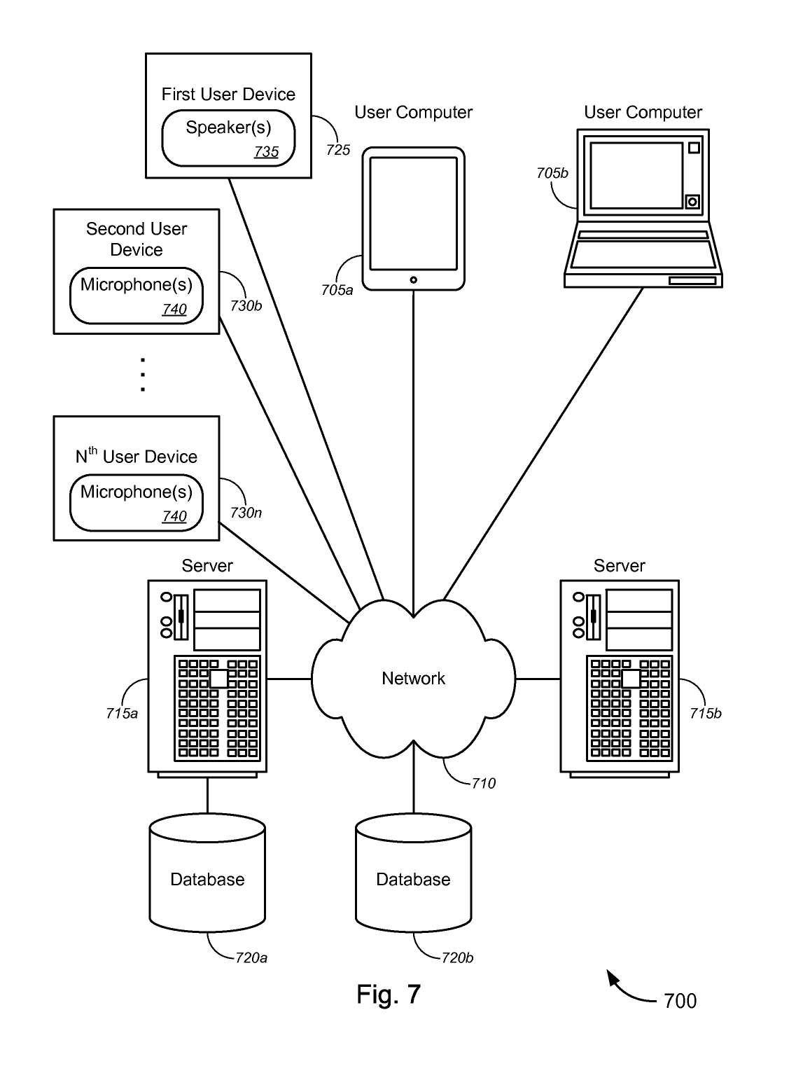

As noted above, a set of embodiments comprises systems and methods for providing audio-based remote control functionality. FIG. 7 illustrates a schematic diagram of a system 700 that can be used in accordance with one set of embodiments. The system 700 can include one or more user computers 705. In particular, a user computer 705 can be a first user device 725, or second through N^{th} user devices 730b-730n. In some embodiments, the first user device 725 might be an audio-based remote control device, while each of the second through N^{th} user devices might be devices to be controlled, as described above with respect to the embodiments of FIGS. 3, 4, and 5A. Alternatively, the first user device 725 might be a device to be controlled, while each of the second through N^{th} user devices might be audio-based remote control devices, as described above with respect to the embodiments of FIGS. 1, 2, and 5B (except that in FIG. 5B, the third user device is a device to be controlled). More generally, a user computer 705 can be a general purpose personal computer (including, merely by way of example, desktop computers, workstations, tablet computers, laptop computers, handheld computers, mobile phones, smart phones, and/or the like), running any appropriate operating system, several of which are available from vendors such as Apple, Microsoft Corp., as well as a variety of commercially-available UNIX™ or UNIX-like operating systems. A user computer 705 can also have any of a variety of applications, including one or more applications configured to perform methods provided by various embodiments (as described above, for example), as well as one or more office applications, database client and/or server applications, and/or web browser applications. Alternatively, a user computer 705 can be any other electronic device, such as a thin-client computer, Internet-enabled mobile telephone, and/or personal digital assistant, capable of communicating via a network (e.g., the network 710 described below) and/or of displaying and navigating web pages or other types of electronic documents. Although the exemplary system 700 is shown with two user computers 705, any number of user computers can be supported.

Certain embodiments operate in a networked environment, which can include a network 710. The network 710 can be any type of network familiar to those skilled in the art that can support data communications using any of a variety of commercially-available (and/or free or proprietary) protocols, including, without limitation, TCP/IP, SNA™, IPX™, AppleTalk™, and/or the like. Merely by way of example, the network 710 can include a local area network (“LAN”), including, without limitation, a fiber network, an Ethernet network, a Token-Ring™ network, and/or the like; a wide-area network; a wireless wide area network (“WWAN”); a virtual network, such as a virtual private network (“VPN”); the Internet; an intranet; an extranet; a public switched telephone network (“PSTN”); an infra-red network; a wireless network, including, without limitation, a network operating under any of the IEEE 802.11 suite of protocols, the Bluetooth™ protocol known in the art, and/or any other wireless protocol; and/or any combination of these and/or other networks.

Embodiments can also include one or more server computers 715. Each of the server computers 715 may be configured with an operating system, including, without limitation, any of those discussed above with respect to the user computers 705, as well as any commercially (or freely) available server operating systems. Each of the servers 715 may also be running one or more applications, which can be configured to provide services to one or more clients 705 and/or other servers 715.

Merely by way of example, one of the servers 715 might be a control server, with the functionality described above. In another embodiment, one of the servers might be a web server, which can be used, merely by way of example, to provide communication between a user computer 705 and a control server, for example, to process requests for web pages or other electronic documents from user computers 705 and/or to provide user input to the control server. The web server can also run a variety of server applications, including HTTP servers, FTP servers, CGI servers, database servers, Java servers, and the like. In some embodiments of the invention, the web server may be configured to serve web pages that can be operated within a web browser on one or more of the user computers 705 to perform operations in accordance with methods provided by various embodiments.

The server computers 715, in some embodiments, might include one or more application servers, which can be configured with one or more applications accessible by a client running on one or more of the client computers 705 and/or other servers 715. Merely by way of example, the server(s) 715 can be one or more general purpose computers capable of executing programs or scripts in response to the user computers 705 and/or other servers 715, including, without limitation, web applications (which might, in some cases, be configured to perform methods provided by various embodiments). Merely by way of example, a web application can be implemented as one or more scripts or programs written in any suitable programming language, such as Java™, C, C#™, or C++, and/or any scripting language, such as Perl, Python, or TCL, as well as combinations of any programming and/or scripting languages. The application server(s) can also include database servers, including, without limitation, those commercially available from Oracle™, Microsoft™, Sybase™′ IBM™, and the like, which can process requests from clients (including, depending on the configuration, dedicated database clients, API clients, web browsers, etc.) running on a user computer 705 and/or another server 715. In some embodiments, an application server can create web pages dynamically for displaying the information in accordance with various embodiments, such as providing a user interface for a control server, as described above. Data provided by an application server may be formatted as one or more web pages (comprising HTML, JavaScript, etc., for example) and/or may be forwarded to a user computer 705 via a web server (as described above, for example). Similarly, a web server might receive web page requests and/or input data from a user computer 705 and/or forward the web page requests and/or input data to an application server. In some cases, a web server may be integrated with an application server.

In accordance with further embodiments, one or more servers 715 can function as a file server and/or can include one or more of the files (e.g., application code, data files, etc.) necessary to implement various disclosed methods, incorporated by an application running on a user computer 705 and/or another server 715. Alternatively, as those skilled in the art will appreciate, a file server can include all necessary files, allowing such an application to be invoked remotely by a user computer 705 and/or server 715.

It should be noted that the functions described with respect to various servers herein (e.g., application server, database server, web server, file server, etc.) can be performed by a single server and/or a plurality of specialized servers, depending on implementation-specific needs and parameters. Further, as noted above, the functionality of one or more servers 715 might be implemented by one or more containers or virtual machines operating in a cloud environment and/or a distributed, cloud-like environment based on shared resources of a plurality of user devices.

In certain embodiments, the system can include one or more data stores 720. The nature and location of the data stores 720 is discretionary: merely by way of example, one data store 720 might comprise a database 720a that stores information about master accounts, assigned user devices, etc. Alternatively and/or additionally, a data store 720b might be a cloud storage environment for storing uploaded images and/or video. As the skilled reader can appreciate, the database 720a and the cloud storage environment 720b might be collocated and/or separate from one another. Some or all of the data stores 720 might reside on a storage medium local to (and/or resident in) a server 715a. Conversely, any of the data stores 720 (and especially the cloud storage environment 720b) might be remote from any or all of the computers 705, 715, so long as it can be in communication (e.g., via the network 710) with one or more of these. In a particular set of embodiments, a database 720a can reside in a storage-area network (“SAN”) familiar to those skilled in the art, and/or the cloud storage environment 720b might comprise one or more SANs. (Likewise, any necessary files for performing the functions attributed to the computers 705, 715 can be stored locally on the respective computer and/or remotely, as appropriate.) In one set of embodiments, the database 720a can be a relational database, such as an Oracle database, that is adapted to store, update, and retrieve data in response to SQL-formatted commands. The database might be controlled and/or maintained by a database server, as described above, for example.

As noted above, the system can also include a first user device 725, and a second through N^{th} user devices 730b-730n. In some embodiments, the first user device 725 might be an audio-based remote control device, and might correspond to any of first user device 305 and/or user computer 705. The second through N^{th} user devices 730b-730n be devices to be controlled, and might correspond to any of second through N^{th} user devices 310 or 315, and/or user computer 705. Alternatively, the first user device 725 might be a device to be controlled, and might correspond to any of first user device 105a and/or user computer 705. The second through N^{th} user devices might be audio-based remote control devices, and might correspond to any of second through N^{th} user devices 105b-105n, and/or user computer 705. Using the techniques described herein, the first user device 725 or the second through Nth user device 730b-730n, as audio-based remote control devices, might receive user input, might generate audio-based commands based on the received user input, and might send the audio-based commands via one or more speakers 735 to one or more of the second through N^{th} user devices 730b-730n or to the first user device 725, each as devices to be controlled, which might receive the audio-based commands using an audio input device (e.g., microphone 740 or the like), might convert the audio-based commands into regular commands, and might perform the functions associated with the regular commands. In some instances, the device that receives the audio-based commands might be an intermediate device that receives the audio-based commands using an audio input device (e.g., microphone 740 or the like), converts the audio-based commands into regular commands, and relays the regular commands to a device to be controlled, which then might receive the regular commands and might perform the functions associated with the regular commands. In some cases, select ones of the first user device 725 or the one or more of the second through N^{th} user devices 730b-730n might establish a network connection with a network (e.g., network 710), and might receive updates with regards to converting between audio-based commands and commands associated with one or more functions for each of one or more different user devices to be controlled. In some cases, the methods described above with respect to FIGS. 4 and 5 might be applied to the user devices 725 and 730.

While certain features and aspects have been described with respect to exemplary embodiments, one skilled in the art will recognize that numerous modifications are possible. For example, the methods and processes described herein may be implemented using hardware components, software components, and/or any combination thereof. Further, while various methods and processes described herein may be described with respect to particular structural and/or functional components for ease of description, methods provided by various embodiments are not limited to any particular structural and/or functional architecture but instead can be implemented on any suitable hardware, firmware, and/or software configuration. Similarly, while certain functionality is ascribed to certain system components, unless the context dictates otherwise, this functionality can be distributed among various other system components in accordance with the several embodiments.

Moreover, while the procedures of the methods and processes described herein are described in a particular order for ease of description, unless the context dictates otherwise, various procedures may be reordered, added, and/or omitted in accordance with various embodiments. Moreover, the procedures described with respect to one method or process may be incorporated within other described methods or processes; likewise, system components described according to a particular structural architecture and/or with respect to one system may be organized in alternative structural architectures and/or incorporated within other described systems. Hence, while various embodiments are described with—or without—certain features for ease of description and to illustrate exemplary aspects of those embodiments, the various components and/or features described herein with respect to a particular embodiment can be substituted, added, and/or subtracted from among other described embodiments, unless the context dictates otherwise. Consequently, although several exemplary embodiments are described above, it will be appreciated that the invention is intended to cover all modifications and equivalents within the scope of the following claims.

What is claimed is:

1. A method, comprising:
receiving, with a first user device, user input indicating user selection of one or more functions to be performed by a second user device;
generating, with the first user device, a first set of commands, based at least in part on the received user input;
generating, with the first user device, an audio-based set of commands, based at least in part on the first set of commands;
emitting, with one or more speakers of the first user device, the generated audio-based set of commands for instructing the second user device to perform the one or more functions.

2. The method of claim 1, wherein the first user device comprises one of a dedicated remote control device associated with the second user device, a universal remote control device, or a mobile user device.

3. The method of claim 2, wherein the mobile user device comprises one of a smart phone, a mobile phone, a tablet computer, a gaming console, a portable gaming device, a laptop computer, or a desktop computer.

4. The method of claim 1, wherein the second user device comprises one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, or a consumer electronic device sold without a dedicated remote controller.

5. The method of claim 1, wherein the second user device comprises one of a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

6. The method of claim 1, wherein the audio-based set of commands comprises a plurality of unique tones that are each mapped to a corresponding one of the one or more functions.

7. The method of claim 6, wherein the plurality of unique tones comprises a plurality of audible tones.

8. The method of claim 7, wherein emitting the generated audio-based set of commands comprises emitting, with the one or more speakers of the first user device, the plurality of audible tones at a sound pressure level below auditory threshold.

9. The method of claim 6, wherein the plurality of unique tones comprises at least one of a plurality of infra-sonic tones or a plurality of ultra-sonic tones.

10. The method of claim 9, wherein the audio-based set of commands comprises one or more masking audible tones overlaid on each of the at least one of the plurality of infra-sonic tones or the plurality of ultra-sonic tones, wherein the one or more masking audible tones are unrelated or unassociated with any functions of the second user device.

11. The method of claim 6, wherein the plurality of unique tones comprises a plurality of audible tones that are harmonics of each other.

12. The method of claim 6, wherein the plurality of unique tones comprises one or more musical cords.

13. The method of claim 6, wherein the plurality of unique tones comprise two or more unique tones that are classified into audibly distinguishable groups, each group being associated with a user device separate from other user devices associated with other groups.

14. The method of claim 6, wherein the plurality of unique tones comprise one or more tones that are correlated with at least one of phonetic sound of a command, meaning of a command, or evoked sense of a command.

15. The method of claim 6, wherein the plurality of unique tones comprises one or more tones each having at least one pattern embedded therein, wherein each tone, although audibly indistinguishable to a human, is distinguishable by a receiver from a combination of pattern and tone.

16. The method of claim 1, wherein generating the audio-based set of commands, based at least in part on the first set of commands, comprises generating, with the first user device, an audio-based set of commands, based at least in part on the first set of commands, using forward error control (“FEC”) code.

17. The method of claim 16, wherein the FEC code comprises one of repetition code, binary convolutional code, block code, low density parity check code, or a combination of these codes.

18. The method of claim 1, further comprises:
modulating, with the first user device, the audio-based set of commands using orthogonal frequency-division multiplexing (“OFDM”), prior to emitting the generated audio-based set of commands.

19. The method of claim 1, further comprises:
modulating, with the first user device, the audio-based set of commands using spreading sequence modulation, prior to emitting the generated audio-based set of commands.

20. The method of claim 1, further comprises:
modifying, with the first user device, frequency range of sound of the generated audio-based set of commands based on at least one of frequency range of the one or more speakers or sampling rate used with the one or more speakers.

21. The method of claim 1, wherein the audio-based set of commands comprises a packet field, a packet header field, and a message field, and wherein the method further comprises:
performing, with the first user device and prior to emitting the generated audio-based set of commands, a cyclic redundancy check (“CRC”) on the audio-based set of commands, by appending a CRC check value for protecting at least one of the packet field, the packet header field, or the message field.

22. The method of claim 1, wherein the audio-based set of commands comprises at least one of a source address, a destination address, a target device type, or a target device model number.

23. The method of claim 1, further comprising:
encrypting, with the first user device, the audio-based set of commands, prior to emitting the generated audio-based set of commands.

24. The method of claim 1, further comprising:
measuring, with a microphone of the first user device, background noise level prior to emitting the generated audio-based set of commands;
wherein emitting the generated audio-based set of commands is performed based at least in part on a determination that the measured background noise level does not conflict with the generated audio-based set of commands when emitted.

25. The method of claim 24, further comprising:
adjusting, with the first user device, volume of the one or more speakers based at least in part on the measured background noise level.

26. The method of claim 1, wherein the second user device responds to the emitted generated audio-based set of commands with one of an audible acknowledgement (“ACK”) or an audible negative ACK (“NACK”).

27. The method of claim 26, further comprising:
adjusting, with the first user device, volume of the one or more speakers in response to one of receiving NACK, not receiving ACK, volume level of ACK, or volume level of NACK from the second user device.

28. The method of claim 1, wherein the user input comprises one of a typed user input or a voice user input that does not match any of a preselected group of commands, wherein generating at least one of the first set of commands or the audio-based set of commands comprises embedding the one of typed user input or voice user input as message data in the at least one of the first set of commands or the audio-based set of commands.

29. A method, comprising:
receiving, with a first user device, an audio-based set of commands emitted from one or more speakers of a second user device;
converting, with the first user device, the received audio-based set of commands into a first set of commands, wherein the first set of commands causes one of the first user device or a third user device to perform one or more functions.

30. The method of claim 29, wherein the first user device comprises one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

31. The method of claim 29, wherein the first user device comprises an audio receiver that communicatively couples to the third user device, and wherein the third user device comprises one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker.

32. The method of claim 29, wherein the second user device comprises one of a dedicated remote control device associated with the second user device, a universal remote control device, a smart phone, a mobile phone, a tablet computer, a gaming console, a portable gaming device, a laptop computer, or a desktop computer.

33. The method of claim 29, wherein the audio-based set of commands comprises a plurality of unique tones that are each mapped to a corresponding one of the one or more functions.

34. The method of claim 33, wherein the plurality of unique tones comprise a plurality of audible tones.

35. The method of claim 34, wherein emitting the generated audio-based set of commands comprises emitting, with the one or more speakers of the first user device, the plurality of audible tones at a sound pressure level below auditory threshold.

36. The method of claim 33, wherein the plurality of unique tones comprise at least one of a plurality of infra-sonic tones or a plurality of ultra-sonic tones.

37. The method of claim 36, wherein the audio-based set of commands comprises one or more masking audible tones overlaid on each of the at least one of the plurality of infra-sonic tones or the plurality of ultra-sonic tones, wherein the one or more masking audible tones are unrelated or unassociated with any functions of the second user device.

38. A user device having remote control functionality, comprising:
one or more speakers;
at least one processor; and
a non-transitory computer readable medium in communication with the at least one processor, the computer readable medium having encoded thereon computer software comprising a set of instructions executable by the at least one processor to control operation of the user device, the set of instructions comprising:
instructions for receiving user input indicating user selection of one or more functions to be performed by a second user device;
instructions for generating a first set of commands, based at least in part on the received user input;
instructions for generating an audio-based set of commands, based at least in part on the first set of commands;
instructions for emitting, with the one or more speakers, the generated audio-based set of commands for instructing the second user device to perform the one or more functions.

39. The user device of claim 38, wherein the user device comprises one of a dedicated remote control device associated with the second user device, a universal remote control device, a smart phone, a mobile phone, a tablet computer, a gaming console, a portable gaming device, a laptop computer, or a desktop computer.

40. A user device, comprising:
one or more microphones;
at least one processor; and
a non-transitory computer readable medium in communication with the at least one processor, the computer readable medium having encoded thereon computer software comprising a set of instructions executable by the at least one processor to control operation of the user device, the set of instructions comprising:
instructions for receiving, with the one or more microphones, an audio-based set of commands emitted from one or more speakers of a second user device; and
instructions for converting the received audio-based set of commands into a first set of commands that causes one of the user device or a third user device to perform one or more functions.

41. The user device of claim 40, wherein the user device comprises one of a video communication device, a video calling device, an image capture device, a presence detection device, a video recording device, a video playback device, a set-top box, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker, and wherein the set of instructions further comprises:
instructions for performing the one or more functions, based at least in part on the first set of commands.

42. The user device of claim 40, wherein the user device comprises an audio receiver that communicatively couples to the third user device, wherein the third user device comprises one of a video communication device, a video calling device, an image capture device, a presence detection device, a video recording device, a video playback device, an audio recording device, an audio playback device, a tablet computer, a laptop computer, a desktop computer, a residential network device, a commercial network device, a toy vehicle, a toy aircraft, a consumer electronic device sold without a dedicated remote controller, a television, a kitchen appliance, a thermostat, a home security control device, a door-lock mechanism, a door opening/closing mechanism, a window opening/closing mechanism, a skylight opening/closing mechanism, a window covering adjustment system, a lighting system, or an external speaker, and wherein the set of instructions further comprises:
instructions for sending the first set of commands to the third user device, wherein the first set of commands causes the third user device to perform the one or more functions.

43. A system, comprising:
a first user device, comprising:
one or more speakers;
at least one first processor; and
a first non-transitory computer readable medium in communication with the at least one first processor, the first non-transitory computer readable medium having encoded thereon computer software comprising a first set of instructions executable by the at least one first processor to control operation of the first user device;
a second user device, comprising:
one or more microphones;
at least one second processor; and
a second non-transitory computer readable medium in communication with the at least one second processor, the second non-transitory computer readable medium having encoded thereon computer software comprising a second set of instructions executable by the at least one second processor to control operation of the second user device;
wherein the first set of instructions comprises:
instructions for receiving user input indicating user selection of one or more functions to be performed by one of the second user device or a third user device;
instructions for generating a first set of commands, based at least in part on the received user input;
instructions for generating an audio-based set of commands, based at least in part on the first set of commands; and
instructions for emitting, with the one or more speakers, the generated audio-based set of commands for instructing the second user device to perform the one or more functions; and
wherein the second set of instructions comprises:
instructions for receiving, with the one or more microphones, the audio-based set of commands emitted from the one or more speakers of the first user device; and
instructions for converting the received audio-based set of commands into a second set of commands that causes one of the second user device or the third user device to perform the one or more functions.

44. The system of claim 43, wherein the audio-based set of commands comprises a plurality of unique tones that are each mapped to a corresponding one of the one or more functions.

45. The system of claim 44, wherein the plurality of unique tones comprise a plurality of audible tones.

46. The system of claim 45, wherein emitting the generated audio-based set of commands comprises emitting, with the one or more speakers of the first user device, the plurality of audible tones at a sound pressure level below auditory threshold.

47. The system of claim 44, wherein the plurality of unique tones comprise at least one of a plurality of infra-sonic tones or a plurality of ultra-sonic tones.

48. The system of claim 47, wherein the audio-based set of commands comprises one or more masking audible tones overlaid on each of the at least one of the plurality of infra-sonic tones or the plurality of ultra-sonic tones, wherein the one or more masking audible tones are unrelated or unassociated with any functions of the second user device.
